(19) United States
(12) Patent Application Publication
(10) Pub. No.: US 2026/0007038 A1
(43) Pub. Date: Jan. 1, 2026

(54) ORGANIC LIGHT EMITTING DISPLAY DEVICE

(71) Applicant: LG Display Co., Ltd., Seoul (KR)

(72) Inventors: Dahye KWON, Paju-si (KR); DongYoon KIM, Paju-si (KR); Taehee KO, Paju-si (KR)

(73) Assignee: LG Display Co., Ltd., Seoul (KR)

(21) Appl. No.: 19/251,578

(22) Filed: Jun. 26, 2025

(30) Foreign Application Priority Data
Jun. 28, 2024 (KR) 10-2024-0085357

(51) Int. Cl. H10K 59/80; H10K 59/35

(52) U.S. Cl. CPC H10K 59/80518; H10K 59/353; H10K 59/878

(57) ABSTRACT

An organic light emitting display device can include a substrate, a subpixel disposed on the substrate, a first electrode provided in the subpixel and including a reflective electrode and a transparent electrode disposed on the reflective electrode, a light emitting layer disposed on the first electrode, and a second electrode disposed on the light emitting layer. The transparent electrode includes a first portion having a first height, and a second portion having a second height different from the first height.

### CROSS-REFERENCE TO RELATED APPLICATION

This application claims priority to Korean Patent Application No. 10-2024-0085357 filed in the Republic of Korea on Jun. 28, 2024, which is hereby expressly incorporated by reference in its entirety into the present application.

### BACKGROUND

### Technical Field

The present disclosure relates to a device and particularly to, for example, without limitation, an organic light emitting display device.

### Discussion of the Related Art

As the information society develops, the demand for display devices for displaying images is increasing in various forms. Accordingly, various display devices such as liquid crystal displays (LCDs), plasma display panels (PDPs), and organic light emitting displays (OLEDs) are being utilized recently.

Among the display devices, organic light emitting display devices are self-luminous, and have superior viewing angles and contrast ratios compared to liquid crystal displays (LCDs), and do not require a separate backlight, making them lightweight and thin, and have the advantage of low power consumption. In addition, the organic light emitting display devices can be driven by low direct current voltage, have a fast response speed, and have the advantage of low manufacturing costs.

An organic light emitting display device includes subpixels each having a light emitting layer between a cathode that injects electrons and an anode that injects holes. The organic light emitting display device is a display device that utilizes the principle that when electrons generated from the cathode and holes generated from the anode are injected into the light emitting layer, the injected electrons and holes combine to generate excitons, and the generated excitons fall from an excited state to a ground state to emit light.

When forming a plurality of subpixels that emit white, red, green, and blue colors, the frontal light emission efficiency of each subpixel can be increased by a micro cavity. However, in the case of a subpixel that emits white color, if a micro cavity is used, the wavelength can change when the pixel is viewed from a certain angle from the front, which can result in a deviation in color reproduction compared to when viewed from the front. In this case, a consumer looking at a device equipped with a display panel, such as a mobile phone, a TV, a tablet, and a car screen, can feel uncomfortable due to a display screen with a reduced aesthetic appeal due to differences in color reproducibility when viewed from the front and the side.

### SUMMARY OF THE DISCLOSURE

The present disclosure has been designed to solve or address the above mentioned problems and limitations associated with the related art, and aims to provide an organic light emitting display device having high color reproducibility, while having high light emission efficiency at the front and not significantly reducing light emission efficiency at a side at a certain angle from the front.

In order to achieve the above objects, the present disclosure provides an organic light emitting display device including a substrate, a subpixel disposed on the substrate, a first electrode provided in the subpixel and including a reflective electrode and a transparent electrode disposed on the reflective electrode, a light emitting layer disposed on the first electrode, and a second electrode disposed on the light emitting layer, wherein the transparent electrode includes a first portion having a first height, and a second portion having a second height different from the first height.

Furthermore, the present disclosure provides an organic light emitting display device including a substrate, a plurality of subpixels including a first subpixel and a second subpixel disposed on the substrate, a first electrode provided in each of the plurality of subpixels and including a reflective electrode and a transparent electrode on the reflective electrode, a light emitting layer disposed on the first electrode, and a second electrode disposed on the light emitting layer, wherein the transparent electrode of the first subpixel includes a first portion having a first height and a second portion having a second height, and wherein the transparent electrode of the second subpixel is formed with the first height.

Furthermore, the present disclosure provides an organic light emitting display device including a substrate, a plurality of subpixels provided on the substrate, a first electrode provided in each of the plurality of subpixels, a light emitting layer disposed on the first electrode, and a second electrode disposed on the light emitting layer, wherein at least one of the plurality of subpixels implements a microcavity effect for at least two of red, green, and blue light.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a perspective view schematically showing a display device according to one or more embodiments of the present disclosure.

FIG. 2 is a schematic plan view of a display device according to one or more embodiments of the present disclosure.

FIG. 3 is a plan view of a subpixel according to one or more embodiments of the present disclosure.

FIG. 4 is a cross-sectional view of a subpixel according to one or more embodiments of the present disclosure. In this case, FIG. 4 corresponds to a cross-section along line I-I′ of FIG. 3.

FIG. 5 is a plan view of a subpixel according to another embodiment of the present disclosure.

FIG. 6 is a plan view of a subpixel according to another embodiment of the present disclosure.

FIG. 7 is a cross-sectional view of a subpixel according to another embodiment of the present disclosure. In this case, FIG. 7 corresponds to a cross-section along line II-II′ of FIG. 6.

FIG. 8 is a plan view of a subpixel according to another embodiment of the present

FIG. 9A is a schematic cross-sectional view of a subpixel according to another embodiment of the present disclosure. In this case, FIG. 9A is an enlarged view of area A of FIG. 7.

FIG. 9B is a schematic cross-sectional view of a subpixel according to another embodiment of the present disclosure. In this case, FIG. 9B is an enlarged view of area A of FIG. 7.

FIG. 10A is a graph of intensity according to wavelength at the front of a subpixel according to an embodiment of the present disclosure and a subpixel according to a comparative example. FIG. 10B is a graph of intensity according to wavelength at the side of a subpixel according to an embodiment of the present disclosure and a subpixel according to a comparative example.

FIGS. 11A to 11H are process cross-sectional views of a subpixel according to one or more embodiments of the present disclosure. In this case, FIGS. 11A to 11H correspond to a cross-section along line II-II′ of FIG. 6.

FIG. 12 is a cross-sectional view of a subpixel according to another embodiment of the present disclosure. In this case, FIG. 12 corresponds to a cross-section along line II-II′ of FIG. 6.

FIGS. 13A to 13C are process cross-sectional views of a subpixel according to one or more embodiments of the present disclosure. In this case, FIGS. 13A to 13C correspond to a cross-section along line II-II′ of FIG. 6.

FIGS. 14A and 14B are TEM images of a first electrode provided in a subpixel according to another embodiment of the present disclosure.

FIG. 15 is a plan view of a subpixel according to another embodiment of the present

FIG. 16 is a cross-sectional view of a subpixel according to another embodiment of the present disclosure. In this case, FIG. 16 corresponds to a cross-section along line III-III′ of FIG. 15.

FIG. 17 is a plan view of a subpixel according to another embodiment of the present disclosure.

FIG. 18 is a cross-sectional view of a subpixel according to another embodiment of the present disclosure. In this case, FIG. 18 corresponds to a cross-section along line IV-IV′ of FIG. 17.

FIG. 19 is a plan view of a subpixel according to another embodiment of the present disclosure.

FIG. 20 is a cross-sectional view of a subpixel according to another embodiment of the present disclosure. In this case, FIG. 20 corresponds to a cross-section along line V-V′ of FIG. 19.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or can be briefly discussed. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

The advantages and features of the present disclosure, and the methods for achieving them, will become clear with reference to the embodiments described in detail below together with the accompanying drawings. However, the present disclosure is not limited to the embodiments disclosed below, but can be implemented in various different forms, and these embodiments are provided only to make the disclosure of the present disclosure complete and to fully inform a person having ordinary skill in the art to which the present disclosure belongs of the scope of the disclosure, and the present disclosure is defined only by the scope of the claims.

The shapes, sizes, ratios, angles, numbers, etc. disclosed in the drawings for explaining embodiments of the present disclosure are examples, and therefore the present disclosure is not limited to the matters illustrated. Like reference numerals refer to like elements throughout the specification. In addition, in describing the present disclosure, if it is determined that a detailed description of a related known technology can unnecessarily obscure the gist of the present disclosure, the detailed description will be omitted. When the terms “includes,” “has,” “consists of,” etc. are used in this specification, other parts can be added unless “only” is used. When a component is expressed in singular, it includes a case where the plural is included unless there is a specifically explicit description.

Any implementation described herein as an “example” is not necessarily to be construed as preferred or advantageous over other implementations.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

When interpreting a component, it is interpreted as including the error range even if there is no separate explicit description.

When describing a positional relationship, for example, when the positional relationship between two parts is described as ‘on’, ‘upper’, ‘lower’, ‘next to’, etc., one or more other parts can be located between the two parts, unless ‘right’ or ‘directly’ is used.

When describing a temporal relationship, for example, when describing a temporal relationship using phrases such as ‘after’, ‘following’, ‘next to’, or ‘before’, it can also include cases where there is no continuity, as long as ‘right away’ or ‘directly’ is not used.

Although the terms first, second, etc. are used to describe various components, these components are not limited by these terms. These terms are only used to distinguish one component from another. Accordingly, a first component referred to below can also be a second component within the technical concept of the present disclosure.

Further, when an element or layer is “connected,” “coupled,” or “adhered” to another element or layer denotes that the element or layer can not only be directly connected or adhered to another element or layer, but also be indirectly connected or adhered to another element or layer with one or more intervening elements or layers “disposed,” or “interposed” between the elements or layers, unless otherwise specified. It should be understood to mean that elements can be so disposed to directly contact each other, or can be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example, consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments can be provided so that this disclosure can be sufficiently thorough and complete to assist those skilled in the art to fully understand the scope of the present disclosure. Furthermore, the present disclosure is only defined by scopes of claims.

The individual features of the various embodiments of the present disclosure can be partially or wholly combined or combined with each other, and can be technically linked and driven in various ways, and each embodiment can be implemented independently of each other or can be implemented together in a related relationship.

Hereinafter, various embodiments of the present disclosure will be described in detail with reference to the drawings. All the components of each display device according to all embodiments of the present disclosure are operatively coupled and configured.

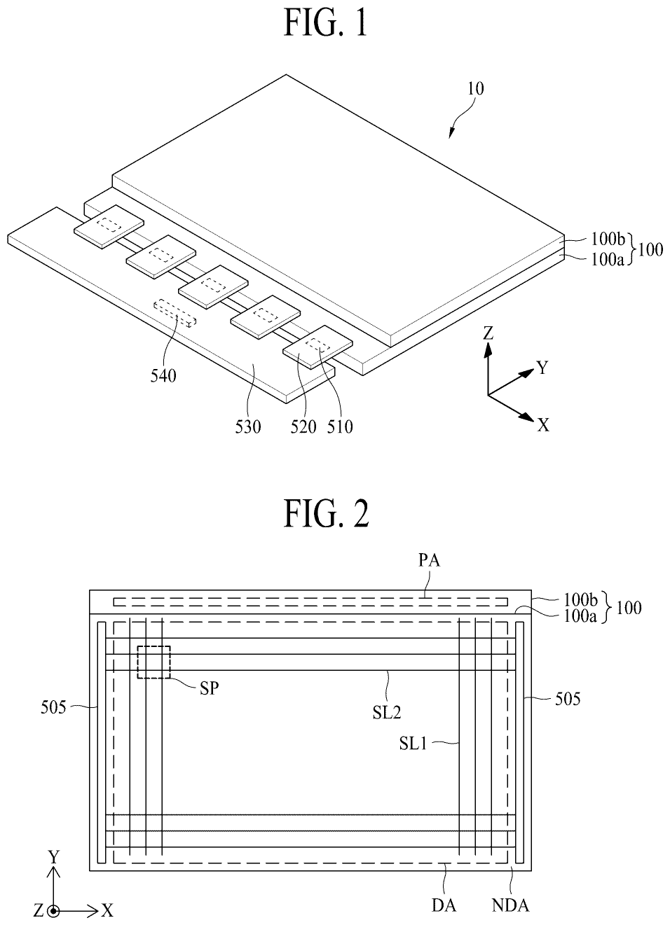

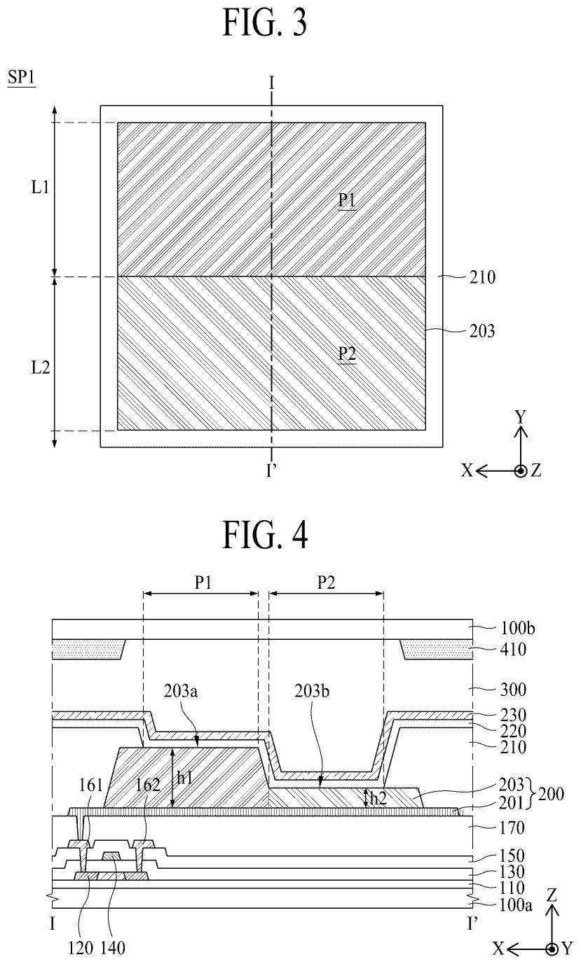

FIG. 1 is a perspective view schematically showing a display device according to one or more embodiments of the present disclosure, and FIG. 2 is a plan view schematically showing a display device according to one or more embodiments of the present disclosure.

Hereinafter, the X-axis represents the direction parallel to a scan line, the Y-axis represents the direction parallel to a data line, and the Z-axis represents the height direction of a display device (10).

The display device (10) according to one embodiment of the present disclosure has been described mainly as being implemented as an organic light emitting display, but can also be implemented as a liquid crystal display, a plasma display panel (PDP), a quantum dot light emitting display (QLED), or an electrophoresis display.

Referring to FIGS. 1 and 2, the display device (10) according to one embodiment of the present disclosure includes a display panel (100), a source drive integrated circuit (hereinafter referred to as “IC”) (510), a flexible film (520), a circuit board (530), and a timing control unit (540).

The display panel (100) includes the first substrate (100a) and the second substrate (100b) facing each other. The second substrate (100b) can be an encapsulation substrate. The first substrate (100a) can be a plastic film, a glass substrate, or a silicon wafer substrate formed using a semiconductor process. The second substrate (100b) can be a plastic film, a glass substrate, or an encapsulation film. The first substrate (100a) and the second substrate (100b) can be made of a transparent material.

The display panel (100) can be divided into a display area (DA) where a plurality of pixels (SP) are formed to display an image and a non-display area (NDA) where no image is displayed.

The display area (DA) can be provided with first signal lines (SL1), second signal lines (SL2) and the plurality of pixels (SP), and the non-display area (NDA) can be provided with a pad area (PA) in which pads are arranged and at least one scan driving unit (505).

The first signal lines (SL1) can extend in a first direction (e.g., in the Y-axis direction) and can intersect the second signal lines (SL2) in the display area (DA). The second signal lines (SL2) can extend in a second direction (e.g., in the X-axis direction) in the display area (DA). The plurality of pixels (SP) are provided in an area where the first signal line (SL1) is provided or an area where the first signal line (SL1) and the second signal line (SL2) intersect, and emit a predetermined amount of light to display an image. Meanwhile, the plurality of pixels (SP) can include a first subpixel (SP1) that emits white (W) light, and second to fourth subpixels (SP2 to SP4) that each emit one of red (R), green (G), and blue (B) light.

The source drive IC (510) receives digital video data and a source control signal from the timing control unit (540). The source drive IC (510) converts digital video data into analog data voltages according to the source control signal and supplies the converted data to data lines. When the source drive IC (510) is manufactured as a driving chip, it can be mounted on the flexible film (520) in a COF (chip on film) or COP (chip on plastic) manner.

Wires connecting the pads and the source drive IC (510), and wires connecting the pads and the wires of the circuit board (530) can be formed on the flexible film (520). The flexible film (520) is attached onto the pads using an anisotropic conducting film, thereby connecting the pads and the wires of the flexible film (520).

The circuit board (530) can be attached to the flexible films (520). The circuit board (530) can have a plurality of circuits implemented with driving chips mounted thereon. For example, the timing control unit (540) can be mounted on the circuit board (530). The circuit board (530) can be a printed circuit board or a flexible printed circuit board.

The timing control unit (540) receives digital video data and a timing signal from an external system board. The timing control unit (540) generates a gate control signal for controlling the operation timing of the scan driving unit based on the timing signal and a source control signal for controlling the source drive ICs (510). The timing control unit (540) supplies the gate control signal to the scan driving unit (505) and the source control signal to the source drive ICs (510).

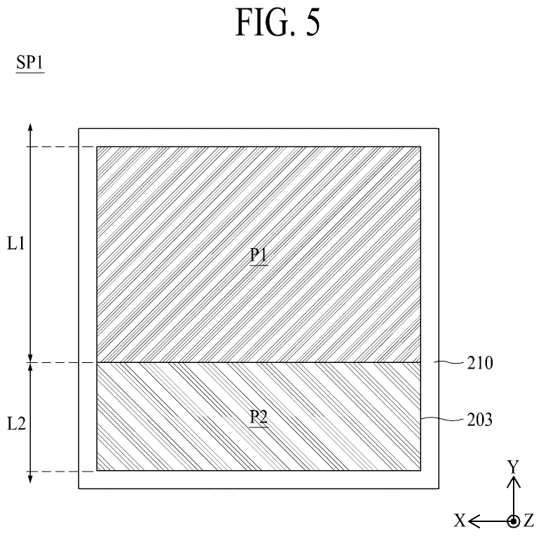

FIG. 3 is a plan view of a subpixel according to one embodiment of the present disclosure.

Referring to FIG. 3, a subpixel according to an embodiment of the present disclosure can be any one of white (W), red (R), green (G), and blue (B) subpixels. For example, a subpixel according to an embodiment of the present disclosure can be a first subpixel (SP1) that emits white (W).

The first subpixel (SP1) includes a transparent electrode (203) and a bank (210) provided to surround the transparent electrode (203). A portion that is not covered by the bank (210) provided around the transparent electrode (203) and is exposed to the outside can be a light emitting area. Accordingly, when the first subpixel (SP1) is driven, light can be emitted from a portion of the exposed transparent electrode (203) except for a portion covered by the bank (210) and recognized by the user.

According to one embodiment of the present disclosure, the transparent electrode (203) can include portions having different heights (or thicknesses) in a third direction (Z), for example, in the height direction. In this case, by the portions of the transparent electrode (203) having different heights, the first subpixel (SP1) can include a first region (P1) and a second region (P2) having different optical characteristics.

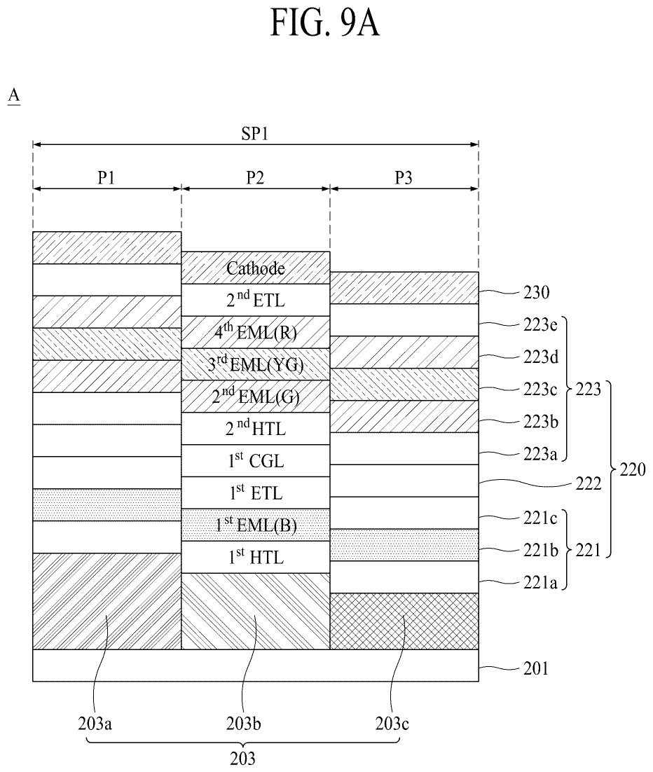

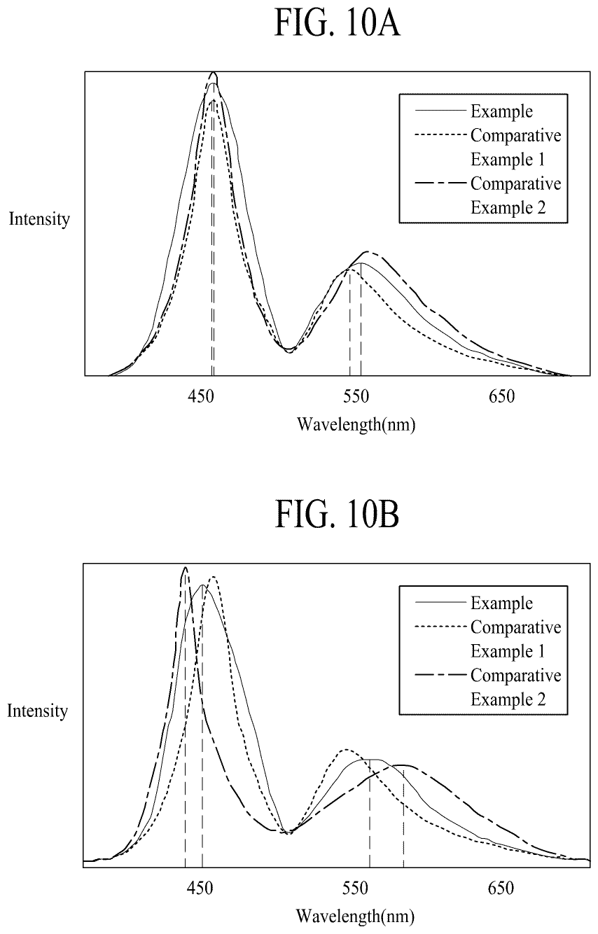

In FIG. 3, the height of the third direction (Z) of the transparent electrode (203) is adjusted to configure the first region (P1) and the second region (P2) in the form of, for example, 2 rows and 1 column, but the embodiment of the present disclosure is not limited thereto, and can be configured in various forms according to the technical level of a person skilled in the art. Accordingly, as another example, like the embodiment of FIG. 6, the first region (P1) to the third region (P3) can be arranged in the form of 3 rows and 1 column, and like the embodiment of FIG. 8, the 1-1 region (Pla) to the 3-3 region (P3c) can be arranged in the form of 3 rows and 3 columns.

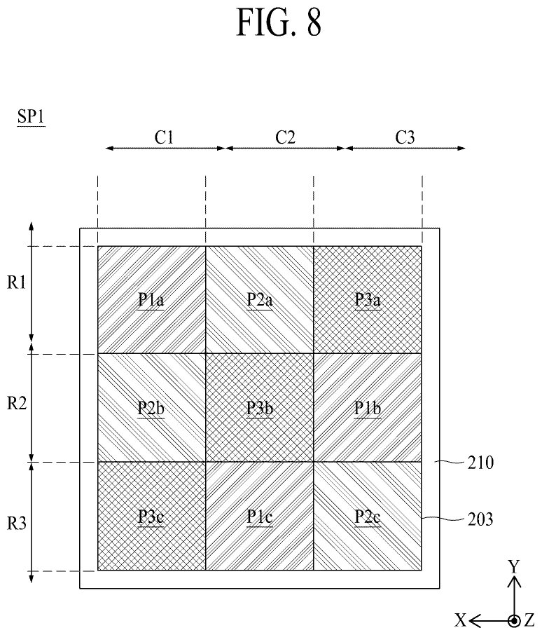

Referring to FIG. 3, in the first subpixel (SP1), the first region (P1) and the second region (P2) can have a first length (L1) and a second length (L2) in the first direction (Y), respectively. Although only an example in which the first length (L1) of the first region (P1) and the second length (L2) of the second region (P2) are formed to be the same is illustrated, the present disclosure is not limited thereto, and as in the embodiment of FIG. 5 described below, the first length (L1) and the second length (L2) can be different.

According to one embodiment of the present disclosure, the first region (P1) can be formed at a height that forms a micro cavity with one of red (R) light, green (G) light, and blue (B) light, and the second region (P2) can be formed at a height that forms a micro cavity with the other of red (R) light, green (G) light, and blue (B) light. Since the transparent electrodes (203) provided in the first subpixel (SP1) have different heights, the first region (P1) and the second region (P2) can be formed to have different optical characteristics, for example, micro cavity characteristics, and while maintaining the light emission efficiency at the front of the first subpixel (SP1) at a certain level, the light emission efficiency at the side can also be improved.

Accordingly, it is possible to implement an organic light emitting display device of superior quality due to high light emission efficiency from both the front and the side. Furthermore, since the difference in light emission efficiency from the front and the side is improved, the difference in color from the front and/or the side is reduced, allowing a user viewing the organic light emitting display device to comfortably view videos and/or images.

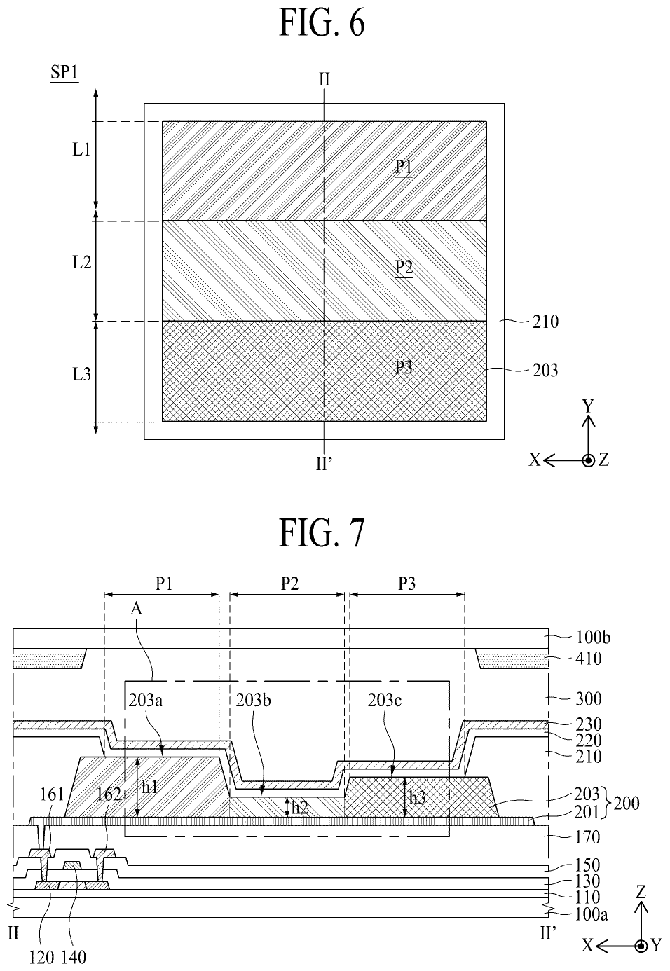

Meanwhile, the fact that the optical characteristics of the first region (P1) and the second region (P2) are provided differently will be explained in more detail later in FIG. 4.

FIG. 4 is a cross-sectional view of a subpixel according to one embodiment of the present disclosure. In this case, FIG. 4 corresponds to a cross-section along line I-I′ of FIG. 3.

As can be seen in FIG. 4, a subpixel according to one embodiment of the present disclosure includes a first substrate (100a), a buffer layer (110), an active layer (120), a gate insulating film (130), a gate electrode (140), an interlayer insulating film (150), a source electrode (161), a drain electrode (162), a planarization layer (170), a first electrode (200), a bank (210), a light emitting layer (220), a second electrode (230), an encapsulation layer (300), a black matrix (410), and a second substrate (100b).

The first substrate (100a) can be made of glass or plastic. In particular, the first substrate (100a) can be made of a transparent plastic having flexible properties, for example, polyimide. When polyimide is used as the first substrate (100a), considering that a high-temperature deposition process is performed on the first substrate (100a), a heat-resistant polyimide that can withstand high temperatures can be used.

The buffer layer (110) can be disposed on the first substrate (100a). The buffer layer (110) can block air and moisture to protect the active layer (120). The buffer layer (110) can be made of an inorganic insulating material such as silicon oxide, silicon nitride, or metal oxide, but is not necessarily limited thereto and can be made of an organic insulating material.

The active layer (120) can be disposed on the buffer layer (110). The active layer (120) can be formed of a semiconductor material, for example, one of amorphous silicon, polycrystalline silicon, and oxide semiconductor material.

The active layer (120) is formed by overlapping the gate electrode (140) and including a channel portion that is not conductive during the conductive process and maintains semiconductor characteristics, a first connection portion provided on one side of the channel portion, for example, the left side, and provided with conductive characteristics through the conductive process, and a second connection portion provided on the other side of the channel portion, for example, the right side, and provided with conductive characteristics through the conductive process. In this case, the conductive process can be, for example, a process of performing plasma treatment on a semiconductor material using the gate electrode (140) as a mask, but is not limited thereto. The first connection portion and the second connection portion formed through the conductive process have excellent conductive characteristics and can thus serve as electrodes or wiring.

The gate insulating film (130) can be disposed on the active layer (120). The gate insulating film (130) can be disposed on the entire surface of the first substrate (100a), but is not limited thereto. A portion of the gate insulating film (130) can be patterned so that one end and the other end of the gate insulating film (130) correspond to one end and the other end of the gate electrode (140), respectively.

The gate insulating film (130) can include, but is not limited to, a silicon nitride film (SiNx) or a silicon oxide film (SiOx). The gate insulating film (130) can be formed of a single layer or multiple layers including an inorganic insulating material and/or an organic insulating material.

The gate electrode (140) can be disposed on the gate insulating film (130).

The gate electrode (140) can include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode (140) can have a structure including one metal layer or a multilayer film structure including at least two metal layers each having different physical properties.

An interlayer insulating film (150) can be disposed on the gate electrode (140). The interlayer insulating film (150) insulates between the gate electrode (140) and the source electrode (161), and further insulates between the gate electrode (140) and the drain electrode (162). The interlayer insulating film (150) can be formed of a single layer or multiple layers including an inorganic insulating material and/or an organic insulating material.

A contact hole can be provided in the interlayer insulating film (150). Accordingly, a part of the upper surface of the first connection portion (122) of the active layer (120) can be exposed by one contact hole, and further, a part of the upper surface of the second connection portion (123) of the active layer (120) can be exposed by another contact hole.

The source electrode (161) and the drain electrode (162) can be disposed on the interlayer insulating film (150).

The source electrode (161) can be electrically connected to one side of the active layer (120) by a contact hole, and the drain electrode (162) can be electrically connected to the other side of the active layer (120) by a contact hole.

The source electrode (161) and the drain electrode (162) can be formed of the same material as the gate electrode (140), but are not limited thereto and can be formed of a material according to knowledge in the art.

The planarization layer (170) can be disposed on the interlayer insulating film (150), the source electrode (161), and the drain electrode (162). The planarization layer (170) can be disposed on the source electrode (161) and the drain electrode (162) so that the upper surface of the planarization layer (170) can be planarized.

The flattening layer (170) is provided with a contact hole, and a part of the upper surface of the source electrode (161) can be exposed through the contact hole. However, depending on the case, a part of the upper surface of the drain electrode (162) can be exposed through the contact hole.

The flattening layer (170) can be composed of an organic insulating material. The flattening layer (170) can be composed of an organic insulating material, such as, for example, an acrylic resin, an epoxy resin, a phenolic resin, a polyamide resin, or a polyimide resin.

The first electrode (200) can be disposed on the planarization layer (170). The first electrode (200) can be pattern-formed to correspond to each subpixel. The first electrode (200) can be electrically connected to the source electrode (161) through a contact hole provided in the planarization layer (170). The first electrode (200) can function as an anode electrode.

The first electrode (200) can include a reflective electrode (201) and a transparent electrode (203).

The reflective electrode (201) is disposed on the planarization layer (170) and can be electrically connected to the source electrode (161) through a contact hole provided in the planarization layer (170). The reflective electrode (201) can be formed by including a material having a relatively high reflectivity. For example, the reflective electrode (201) can be formed by alternately stacking a plurality of layers of aluminum-palladium-copper (APC), aluminum (Al), and indium tin oxide (ITO), a double-layer structure of Ag/ITO, a double-layer structure of APC/ITO, a triple-layer structure of ITO/Ag/ITO, or a triple-layer structure of ITO/APC/ITO, but is not limited thereto, and can be formed by a single metal layer or a plurality of metal layers having a high reflectivity.

The reflective electrode (201) can reflect light emitted from the light emitting layer (220), and the reflected light can travel in the direction of the second substrate (100b).

The transparent electrode (203) can be disposed on the reflective electrode (201). The transparent electrode (203) can be formed by including a material having relatively low reflectivity and high transmittance compared to the reflective electrode (201). For example, the transparent electrode (203) can be formed by including indium zinc oxide (IZO), but is not limited thereto, and can be formed by including various materials according to the level of the art.

According to one embodiment of the present disclosure, the transparent electrode (203) can have a step structure within the first subpixel (SP1). Specifically, the transparent electrode (203) can have a step structure within the light emitting area of the first subpixel (SP1).

The transparent electrode (203) can include a first portion (203a) having a first height (h1) and a second portion (203b) having a second height (h2) within the light emitting area of the first subpixel (SP1). The first height (h1) may, for example, be greater than the second height (h2). In this case, the first height (h1) and the second height (h2) can be defined as the shortest distance from the reflective electrode (201) to the upper surface of the first portion (203a) and the shortest distance to the upper surface of the second portion (203b), respectively.

The transparent electrode (203) can implement micro cavity characteristics between the first electrode (200) and the second electrode (230) by controlling the distance between the first electrode (200) and the second electrode (230), i.e., the resonance distance. In this case, the micro cavity characteristic means a characteristic in which constructive interference occurs when the distance between the first electrode (200) and the second electrode (230) becomes an integer multiple of the half wavelength (λ/2) of the light emitted from the first subpixel (SP1), the light is amplified, and the degree of light amplification continuously increases as the reflection and re-reflection process is repeated between the first electrode (200) and the second electrode (230), thereby improving the external extraction efficiency of the light. The resonance distance can be defined as the distance over which the light emitted from the light emitting layer (220) is reflected and travels between the reflective electrode (201) and the second electrode (230).

According to one embodiment of the present disclosure, by controlling the step structure of the transparent electrode (203), the resonance distance between the reflective electrode (201) and the second electrode (230) can be controlled. Specifically, by controlling the heights of the first portion (203a) and the second portion (203b) of the transparent electrode (203), the resonance distance between the reflective electrode (201) and the second electrode (230) can be controlled. By controlling the resonance distance, a micro cavity can be formed in the red (R) light, green (G) light, and blue (B) light emitted from the light emitting layer (220).

In the first region (P1) overlapping with the first portion (203a), the first height (h1) can be adjusted so that a micro cavity is formed for one of red (R) light, green (G) light, and blue (B) light, and in the second region (P2) overlapping with the second portion (203b), the second height (h2) can be adjusted so that a micro cavity is formed for the other of red (R) light, green (G) light, and blue (B) light. Accordingly, the first height (h1) can be set such that the distance between the reflective electrode (201) and the second electrode (230) is a multiple of a half wavelength of any one of red (R) light, green (G) light, and blue (B) light, and the second height (h2) can be set such that the distance between the reflective electrode (201) and the second electrode (230) is a multiple of a half wavelength of any one of the other of red (R) light, green (G) light, and blue (B) light.

According to one embodiment of the present disclosure, since the heights of the first portion (203a) and the second portion (203b) are formed differently, the first region (P1) and the second region (P2) within the first subpixel (SP1) can have different optical characteristics.

For example, by adjusting the first height (h1) in the first region (P1) overlapping with the first portion (203a), the distance between the reflective electrode (201) and the second electrode (230) can be set to be a multiple of a half wavelength of red (R) light, and by adjusting the second height (h2) in the second region (P2) overlapping with the second portion (203b), the distance between the reflective electrode (201) and the second electrode (230) can be set to be a multiple of a half wavelength of blue (B) light.

In this case, in the first subpixel (SP1), a micro cavity is formed for the red (R) light in the first region (P1), and a micro cavity is formed for the blue (B) light in the second region (P2), so that light emitted from the first subpixel (SP1) can have high light emission efficiency.

According to one embodiment of the present disclosure, by forming micro cavities for light of different colors in the first region (P1) and the second region (P2) within one first subpixel (SP1), when the first subpixel (SP1) expresses white (W) light, the efficiency of at least one of red (R), green (G) and blue (B) light expressing the white (W) light may not be reduced.

Furthermore, even when the first subpixel (SP1) is viewed from the side, for example, at a certain angle with respect to the normal of the light emitting surface, the efficiency of at least one of red (R), green (G) and blue (B) light from the side is not significantly reduced. Therefore, according to an embodiment of the present disclosure, the light emission efficiency in the front view of the first subpixel (SP1) that emits white (W) light can be maintained at or a certain level, while the light emission efficiency in the side view can also be maintained at or a certain level.

The bank (210) can be formed on the first electrode (200). In this case, a portion of the upper surface of the first electrode (200) that is exposed without being covered by the bank (210) serves as a light emitting area.

The bank (210) can be provided to cover a part of the transparent electrode (203). In this case, since the heights of the transparent electrode (203) formed in the first region (P1) and the second region (P2) are different, the thickness of a part of the bank (210) formed on the first part (203a) provided in the first region (P1) can be smaller than the thickness of another part of the bank (210) formed on the second portion (203b) provided in the second region (P2).

The bank (210) can be formed of an organic film such as an acrylic resin, an epoxy resin, a phenolic resin, a polyamide resin, or a polyimide resin.

The light emitting layer (220) can be disposed on the first electrode (200). The light emitting layer (220) can be formed of, for example, a white light emitting layer connected to all pixels.

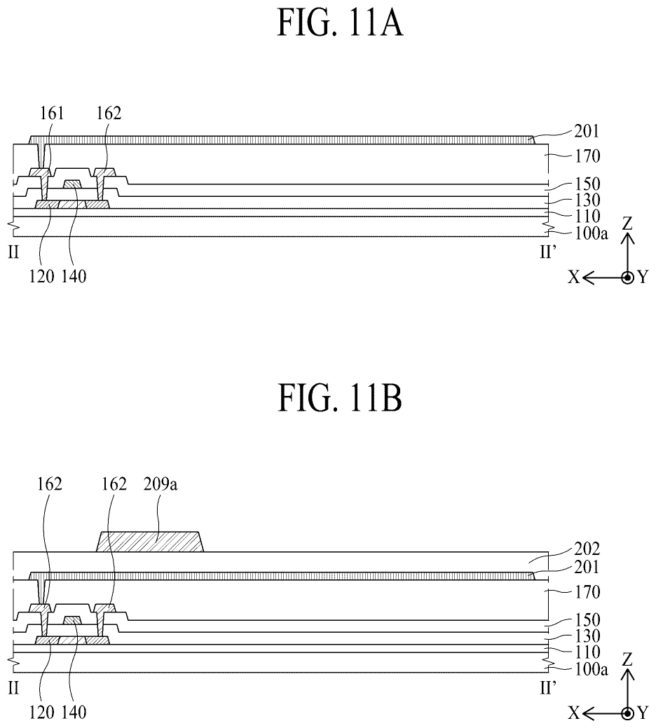

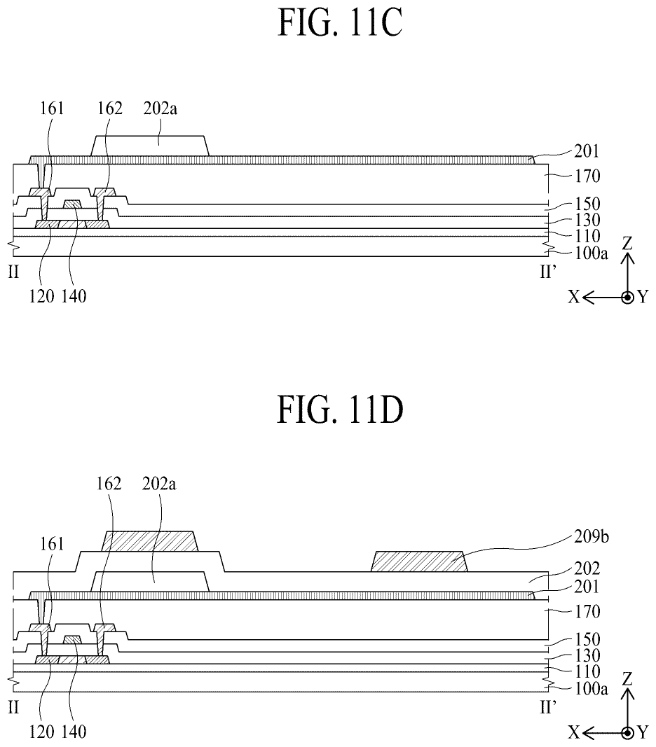

When the above described light emitting layer (220) is formed of a white light emitting layer, the light emitting layer (220) can include, for example, a first stack including a blue (B) light emitting layer, for example, a second stack including a yellow-green (YG) light emitting layer, and a charge generation layer provided between the first stack and the second stack, and as another example, the light emitting layer (220) can include, as illustrated in FIG. 9A, a first stack including a blue (B) light emitting layer, a second stack including a green (G) light emitting layer, a yellow-green (YG) light emitting layer, and a red (R) light emitting layer, in that order, and a charge generation layer provided between the first stack and the second stack. As another example, the light emitting layer (220) can include, for example, a first stack including a blue (B) light emitting layer, a second stack including a red (R) light emitting layer, a yellow-green (YG) light emitting layer, and a green (G) light emitting layer, which are stacked in that order, and a charge generation layer provided between the first stack and the second stack. However, the structure of the light emitting layer (220) is not limited thereto, and can be formed including various configurations and arrangements depending on the level of the art.

According to one embodiment of the present disclosure, the light emitting layer (220) can be formed in a step structure by the transparent electrode (203) formed in a step structure. The light emitting layer (220) can include one part provided in the first region (P1) overlapping the first part (203a) and another part provided in the second region (P2) overlapping the second portion (203b). In this case, one part of the light emitting layer (220) provided in the first region (P1) can be provided at a relatively higher position than the other part of the light emitting layer (220) provided in the second region (P2). For example, one part of the light emitting layer (220) can be formed spaced apart from the reflective electrode (201) by the first height (h1), and another part of the light emitting layer (220) can be formed spaced apart from the reflective electrode (201) by the second height (h2).

The second electrode (230) can be disposed on the light emitting layer (220). The second electrode (230) can function as a cathode. The second electrode (230) can be a common electrode disposed on the entire surface of the first substrate (100a).

The second electrode (230) can have a step structure due to the step structure of the transparent electrode (203). In this case, a part of the second electrode (230) that overlaps with the first part (203a) can be formed at a relatively higher position from the reflective electrode (201) than another part of the second electrode (230) that overlaps with the second portion (203b). The encapsulation layer (300) can be disposed on the second electrode (230).

The encapsulation layer (300) can be disposed on the second electrode (230). The encapsulation layer (300) can be disposed on the entire surface of the first substrate (100a).

The encapsulation layer (300) can be formed of acrylic resin, epoxy resin, polyimide, polyethylene (PE), or silicon oxycarbon (SiOC).

Meanwhile, the encapsulation layer (300) can include a first sealing layer including an inorganic substance, a second sealing layer including an organic substance, and a third sealing layer including an inorganic substance.

The black matrix (410) can be disposed on the encapsulation layer (300). The black matrix (410) can be provided to overlap with the bank (210), and can prevent or reduce light emitted from the first subpixel (SP1) from traveling to another adjacent subpixel and mixing light of different colors to cause color mixing.

The second substrate (100b) can be disposed on the encapsulation layer (300) and the black matrix (410). The second substrate (100b) can be provided at a position facing the first substrate (100a).

The second substrate (100b) can be made of glass or plastic. In particular, the second substrate (100b) can be made of a transparent plastic having flexible properties, for example, polyimide. When polyimide is used as the second substrate (100b), considering that a high-temperature deposition process is performed on the second substrate (100b), a heat-resistant polyimide that can withstand high temperatures can be used.

FIG. 5 is a plan view of a subpixel according to another embodiment of the present disclosure. Meanwhile, the embodiment of FIG. 5 is identical to the embodiment of FIG. 3 except that the first length (L1) and the second length (L2) are provided differently, and therefore, the following description will focus on the different configurations.

As can be seen in FIG. 5, a subpixel according to another embodiment of the present disclosure can be a first subpixel (SP1) that emits white (W). The first subpixel (SP1) includes a transparent electrode (203) and a bank (210) that is provided to surround the transparent electrode (203). In this case, the first subpixel (SP1) can include a first region (P1) having a first length (L1) and a second region (P2) having a second length (L2).

In the embodiment of FIG. 5, unlike the embodiment of FIG. 3 in which the first length (L1) of the first region (P1) is formed to be the same as the second length (L2) of the second region (P2), the first length (L1) of the first region (P1) can be formed to be different from the second length (L2) of the second region (P2).

According to one embodiment, by differently controlling the length (or width) of the first region (P1) and the second region (P2), it is possible to control the micro cavity characteristics formed in the first region (P1) and the micro cavity characteristics formed in the second region (P2), thereby adjusting the light emission efficiency of the first subpixel (SP1).

For example, by controlling the height of the transparent electrode (203) in a third direction (Z), a micro cavity can be formed for red (R) light in the first region (P1), and a micro cavity can be formed for blue (B) light in the second region (P2). In this case, the light emission efficiency of the first subpixel (SP1) can be determined based on the light emission efficiency in the first region (P1) and the proportion of the first region (P1) in the first subpixel (SP1), and the light emission efficiency in the second region (P2) and the proportion of the second region (P2) in the first subpixel (SP1)

Specifically, the light emission efficiency in the first subpixel (SP1) can be determined as shown in [Equation 1] below.

E=(E1⋅×a1)+(E2×a2) [Formula 1]

In this case, E is the light emission efficiency of the first subpixel (SP1), E1 is the light emission efficiency in the first region (P1), E2 is the light emission efficiency in the second region (P2), a1 is the area ratio (L1/(L1+L2)) occupied by the first region (P1) in the first subpixel (SP1), and a2 is the area ratio (L2/(L1+L2)) occupied by the second region (P2) in the first subpixel (SP1).

According to one embodiment of the present disclosure, by controlling the area ratio of the first region (P1) and the second region (P2), the first subpixel (SP1) having improved light emission efficiency can be implemented.

Meanwhile, in FIG. 5, only an example in which a micro cavity is formed for red (R) light in the first region (P1) and a micro cavity is formed for blue (B) light in the second region (P2) has been described, but is not limited thereto. A micro cavity can be formed for red (R) light in the first region (P1) and a micro cavity can be formed for green (G) light in the second region (P2), and can be formed in various shapes depending on the level of the art.

FIG. 6 is a plan view of a subpixel according to another embodiment of the present disclosure. Meanwhile, the embodiment of FIG. 6 is identical to the embodiment of FIG. 3 except that a third region (P3) is additionally provided for the first region (P1) and the second region (P2), and therefore, the following description will focus on the different configuration.

As can be seen in FIG. 6, a subpixel according to another embodiment of the present disclosure can be a first subpixel (SP1) that emits white (W). The first subpixel (SP1) includes a transparent electrode (203) and a bank (210) that is disposed to surround the transparent electrode (203).

The first subpixel (SP1) can include a first region (P1) having a first length (L1), a second region (P2) having a second length (L2), and a third region (P3) having a third length (L3). In this case, the first region (P1) to the third region (P3) can include portions of the transparent electrode (203) having different heights (or thicknesses) in the third direction (Z). Accordingly, the first region (P1) to the third region (P3) of the first subpixel (SP1) can have different optical characteristics due to the portions of the transparent electrode (203) having different heights.

Meanwhile, in FIG. 6, the first region (P1) to the third region (P3) are arranged in a three-row, one-column format, and the first length (L1) to the third length (L3) are shown to have the same shape, but this is not limited thereto.

According to another embodiment of the present disclosure, the first region (P1) can be formed at a height that forms a micro cavity with one of red (R) light, green (G) light, and blue (B) light, the second region (P2) can be formed at a height that forms a micro cavity with another of red (R) light, green (G) light, and blue (B) light, and the third region (P3) can be formed at a height that forms a micro cavity with another of red (R) light, green (G) light, and blue (B) light.

Since the transparent electrode (203) provided in the first subpixel (SP1) has different heights, it can include the first region (P1), the second region (P2), and the third region (P3) having different optical characteristics, for example, micro cavity characteristics, and while maintaining the light emission efficiency at the front of the first subpixel (SP1) at a certain level, the light emission efficiency at the side can also be improved.

Accordingly, it is possible to implement an organic light emitting display device of superior quality due to high light emission efficiency from both the front and the side. Furthermore, since the difference in light emission efficiency from the front and the side is improved, the difference in color from the front and/or the side is reduced, allowing a user viewing the organic light emitting display device to comfortably view videos and/or images.

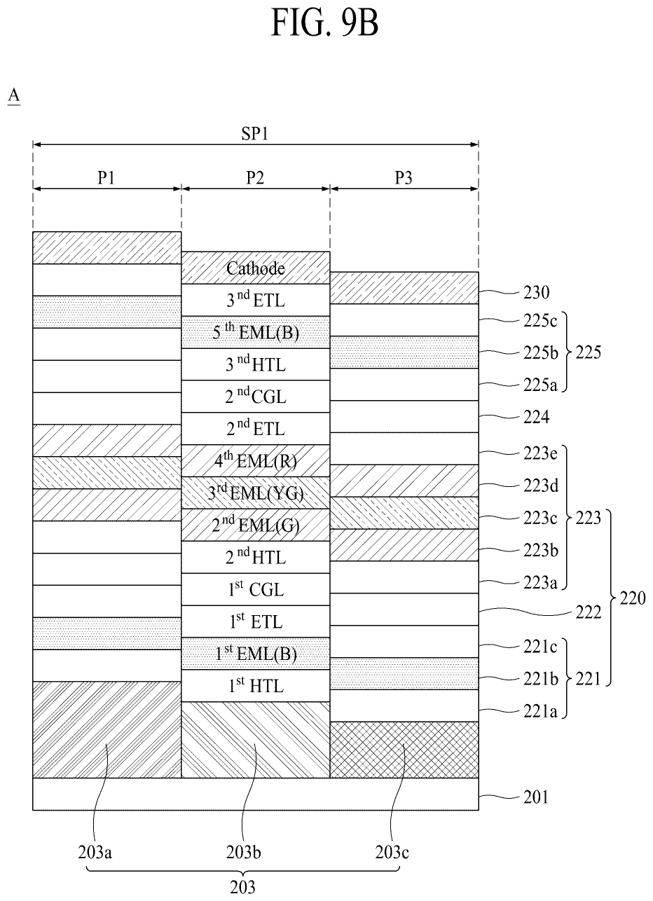

FIG. 7 is a cross-sectional view of a subpixel according to another embodiment of the present disclosure. In this case, FIG. 7 corresponds to a cross-section along line II-II′ of FIG. 6. Meanwhile, the embodiment of FIG. 7 is identical to the embodiment of FIG. 4 except for the third portion (203c) and the third region (P3) of the transparent electrode (203), so the following description will focus on the different configurations.

As can be seen in FIG. 7, a subpixel according to one embodiment of the present disclosure includes a first substrate (100a), a buffer layer (110), an active layer (120), a gate insulating film (130), a gate electrode (140), an interlayer insulating film (150), a source electrode (161), a drain electrode (162), a planarization layer (170), a first electrode (200), a bank (210), a light emitting layer (220), a second electrode (230), an encapsulation layer (300), a black matrix (410), and a second substrate (100b).

According to another embodiment of the present disclosure, the transparent electrode (203) can have a step structure within the first subpixel (SP1). Specifically, the transparent electrode (203) can have a step structure within the light emitting area of the first subpixel (SP1).

The transparent electrode (203) can include a first portion (203a) having a first height (h1), a second portion (203b) having a second height (h2), and a third portion (203c) having a third height (h3) within the light emitting area of the first subpixel (SP1). The first height (h1) can be, for example, greater than the second height (h2) and the third height (h3), and the third height (h3) can be greater than the second height (h2). In this case, the first height (h1) to the third height (h3) can be defined as the shortest distances from the reflective electrode (201) to the upper surfaces of the first portion (203a) to the third portion (203c), respectively.

According to another embodiment of the present disclosure, by controlling the step structure of the transparent electrode (203), the resonance distance between the reflective electrode (201) and the second electrode (230) can be controlled. Specifically, by controlling the height of the first portion (203a) to the third portion (203c) of the transparent electrode (203), the resonance distance between the reflective electrode (201) and the second electrode (230) can be controlled. By controlling the resonance distance, a micro cavity can be formed in the red (R) light, green (G) light, and blue (B) light emitted from the light emitting layer (220).

In the first region (P1) overlapping with the first portion (203a), the first height (h1) can be adjusted so that a micro cavity is formed for one of red (R) light, green (G) light, and blue (B) light, and in the second region (P2) overlapping with the second portion (203b), the second height (h2) can be adjusted so that a micro cavity is formed for another of red (R) light, green (G) light, and blue (B) light, and in the third region (P3) overlapping with the third portion (203c), the third height (h3) can be adjusted so that a micro cavity is formed for another of red (R) light, green (G) light, and blue (B) light. Accordingly, the first height (h1) can be set such that the distance between the reflective electrode (201) and the second electrode (230) is a multiple of a half wavelength of any one of red (R) light, green (G) light, and blue (B) light, the second height (h2) can be set such that the distance between the reflective electrode (201) and the second electrode (230) is a multiple of a half wavelength of any one of the other of red (R) light, green (G) light, and blue (B) light, and the third height (h3) can be set such that the distance between the reflective electrode (201) and the second electrode (230) is a multiple of a half wavelength of any one of the other of red (R) light, green (G) light, and blue (B) light.

According to one embodiment of the present disclosure, since the heights of the first portion (203a) to the third portion (203c) are formed differently, the first region (P1) to the third region (P3) within the first subpixel (SP1) can have different optical characteristics.

For example, in the first region (P1) overlapping with the first portion (203a), the first height (h1) can be adjusted such that the distance between the reflective electrode (201) and the second electrode (230) becomes a multiple of a half-wavelength of red (R) light. In the second region (P2) overlapping with the second portion (203b), the second height (h2) can be adjusted such that the distance between the reflective electrode (201) and the second electrode (230) becomes a multiple of a half-wavelength of blue (B) light. In addition, in the third region (P3) overlapping with the third portion (203c), the third height (h3) can be adjusted such that the distance between the reflective electrode (201) and the second electrode (230) becomes a multiple of a half-wavelength of green (G) light.

In this case, in the first subpixel (SP1), a micro cavity is formed for the red (R) light in the first region (P1), a micro cavity is formed for the blue (B) light in the second region (P2), and a micro cavity is formed for the green (G) light in the third region (P3), so that light emitted from the first subpixel (SP1) can have high light emission efficiency.

According to one embodiment of the present disclosure, by forming micro cavities for light of different colors in the first region (P1) to the third region (P3) within one first subpixel (SP1), when the first subpixel (SP1) expresses white (W) light, the efficiency of at least one of red (R), green (G) and blue (B) light expressing the white (W) light may not be reduced.

Furthermore, even when the first subpixel (SP1) is viewed from the side, for example, at a certain angle with respect to the normal of the light emitting surface, the efficiency of at least one of red (R), green (G) and blue (B) light from the side is not significantly reduced. Therefore, according to an embodiment of the present disclosure, the light emitting efficiency of the front of the first subpixel (SP1) emitting white (W) light can be maintained at a certain level or higher, while the light emitting efficiency from the side can also be maintained at a certain level or higher. Accordingly, even when the first subpixel (SP1) is viewed from the side, white (W) light with improved color purity can be recognized.

According to one embodiment of the present disclosure, the light emitting layer (220) can be formed in a step structure by the transparent electrode (203) formed in a step structure. The light emitting layer (220) can include one part provided in the first region (P1) overlapping the first part (203a), another part provided in the second region (P2) overlapping the second portion (203b), and another part provided in the third region (P3) overlapping the third portion (203c).

FIG. 8 is a plan view of a subpixel according to another embodiment of the present disclosure. Meanwhile, the embodiment of FIG. 8 is identical to the embodiment of FIG. 6 except for the configuration of the 1-1 region (Pla) to the 3-3 region (P3c) provided in the first subpixel (SP1), so the following description will focus on the different configuration.

As can be seen in FIG. 8, the first subpixel (SP1) can be formed to include a plurality of first regions (P1a, P1b, P1c), a plurality of second regions (P2a, P2b, P2c), and a plurality of third regions (P3a, P3b, P3c) by adjusting the height of the transparent electrode (203) in the third direction (Z).

The first subpixel (SP1) can form the plurality of first regions (Pla, P1b, Plc), the plurality of second regions (P2a, P2b, P2c) and the plurality of third regions (P3a, P3b, P3c) in a mesh structure by adjusting the height of the transparent electrode (203) in the third direction (Z). For example, according to an embodiment of the present disclosure, the first subpixel (SP1) can have the plurality of first regions (Pla, P1b, Plc), the plurality of second regions (P2a, P2b, P2c) and the plurality of third regions (P3a, P3b, P3c) arranged in the form of three rows (R1, R2, R3) and three columns (C1, C2, C3).

Meanwhile, in FIG. 8, only one of the plurality of first regions (Pla, P1b, Plc), one of the plurality of second regions (P2a, P2b, P2c), and one of the plurality of third regions (P3a, P3b, P3c) are arranged in each of the rows (R1, R2, R3), or one of the plurality of first regions (P1a, P1b, P1c), one of the plurality of second regions (P2a, P2b, P2c), and one of the plurality of third regions (P3a, P3b, P3c) are arranged in each of the columns (C1, C2, C3), but the present disclosure is not limited thereto. As another example, the first subpixel (SP1) can have the first area (P1) to the third area (P3) arranged in four rows and four columns, and can be arranged in a variety of rows and columns depending on the level of skill in the art.

FIG. 9A is a schematic cross-sectional view of a subpixel according to another embodiment of the present disclosure. In this case, FIG. 9A is an enlarged view of area A of FIG. 7. Therefore, the same configurations are given the same drawing reference numerals, and repeated descriptions are omitted.

As can be seen in FIG. 9A, a first subpixel (SP1) according to one embodiment of the present disclosure can include a reflective electrode (201), a transparent electrode (203), a light emitting layer (220), and a second electrode (230).

According to one embodiment of the present disclosure, the light emitting layer (220) comprises a first stack (221), a first charge generation layer (222) and a second stack (223). In this case, the first stack (221) can emit, for example, blue (B) light, and the second stack (223) can emit, for example, green (G), red (R), and yellow-green (YG) light. In this way, when the light emitted from the first stack (221) and the second stack (223) is combined, white (W) light can be emitted from the first subpixel (SP1).

The first stack (221) can include a first hole transport layer (1st HTL) (221a), a first emission layer (1st EML) (221b), and a first electron transport layer (1st ETL) (221c)

The first hole transport layer (1st HTL) (221a) can be disposed on the transparent electrode (203). The first hole transport layer (1st HTL) (221a) moves the holes from the reflective electrode (201) and the transparent electrode (203) to the first emission layer (1st EML) (221b). Meanwhile, a hole transport layer (HIL) can additionally be provided between the transparent electrode (203) and the first hole transport layer (1st HTL) (221a).

The first emission layer (1st EML) (221b) is a layer that emits blue (B) light, and can emit blue (B) light through the recombination of holes and electrons respectively supplied from the first hole transport layer (1st HTL) (221a) and the first electron transport layer (1st ETL) (221c)

The first electron transport layer (1st ETL) (221c) can be disposed on the first emission layer (1st EML) (221b). The first electron transport layer (1st ETL) (221c) can transport electrons, which have moved from the second electrode (230), to the first emission layer (1st EML) (221b).

The first charge generation layer (222) is disposed on the first stack (221). Specifically, the first charge generation layer (1st CGL) (222) can be disposed between the first stack (221) and the second stack (223). The first charge generation layer (222) can be disposed between the first stack (221) and the second stack (223), thereby controlling the charge balance between the first stack (221) and the second stack (223).

The second stack (223) can be disposed on the first charge generation layer (1st CGL) (222). In this case, the second stack (223) can include a second hole transport layer (2nd HTL) (223a), a second emission layer (2nd EML) (223b), a third emission layer (3rd EML) (223c), a fourth emission layer (4th EML) (223d), and a second electron transport layer (2nd ETL) (223e).

The second hole transport layer (2st HTL) (223a) can be disposed on the first charge generation layer (1st CGL) (222). The second hole transport layer (2st HTL) (223a) can transport holes, which have moved from the first charge generation layer (1st CFL) (222), to the second emission layer (2st EML) (223b).

The second emission layer (2nd EML) (223b) is a layer that emits green (G) light, and can emit green light through the recombination of holes and electrons respectively supplied from the second hole transport layer (2nd HTL) (223a) and the second electron transport layer (2nd ETL) (223e).

The third emission layer (3rd EML) (223c) is a layer that emits yellow-green (YG) light, and can emit yellow-green light through the recombination of holes and electrons respectively supplied from the second hole transport layer (2nd HTL) (223a) and the second electron transport layer (2nd ETL) (223e).

The fourth emission layer (4th EML) (223d) is a layer that emits red (R) light, and can emit red light through the recombination of holes and electrons respectively supplied from the second hole transport layer (2nd HTL) (223a) and the second electron transport layer (2nd ETL) (223e).

The second electron transport layer (2st ETL) (223e) can be disposed on the fourth emission layer (4th EML) (223d). The second electron transport layer (2nd ETL) (223e) can transfer electrons, which have moved from the second electrode (230), to the fourth emission layer (4th EML) (223d). Meanwhile, an electron injection layer (EIL) can additionally be disposed between the second electrode (230) and the second electron transport layer (2nd ETL) (223e).

According to an embodiment of the present disclosure, the first to third portions (203a to 203c) of the transparent electrode (203) can be disposed between the reflective electrode (201) and the first hole transport layer (1st HTL) (221a). As described above with reference to FIG. 7, the first to third portions (203a to 203c) can each be formed to have different heights (or thicknesses). Specifically, the respective heights of the first to third portions (203a to 203c) can be adjusted such that the distances between the reflective electrode (201) and the second electrode (230) correspond to integer multiples of the half-wavelengths of the light emitted from any one of the first to fourth emission layers (1st EML) (221b), (2nd EML) (223b), (3rd EML) (223c), and (4th EML) (223d).

For example, the first height of the first portion (203a) (see h1 in FIG. 7) can be adjusted such that the distance between the reflective electrode (201) and the second electrode (230) becomes an integer multiple of the half-wavelength of red (R) light emitted from the fourth emission layer (4th EML) (223d). The second height of the second portion (203b) (see h2 in FIG. 7) can be adjusted such that the distance between the reflective electrode (201) and the second electrode (230) becomes an integer multiple of the half-wavelength of blue (B) light emitted from the first emission layer (1st EML) (221b). The third height of the third portion (203c) (see h3 in FIG. 7) can be adjusted such that the distance between the reflective electrode (201) and the second electrode (230) becomes an integer multiple of the half-wavelength of green (G) light emitted from the second emission layer (2nd EML) (223b).

FIG. 9B is a schematic cross-sectional view of a subpixel according to another embodiment of the present disclosure. FIG. 9B is an enlarged view of region A in FIG. 7. Except for the configuration of the stacks, the embodiment of FIG. 9B is the same as the embodiment of FIG. 9A. Accordingly, the same reference numerals are used for the same elements, and redundant description will be omitted

As shown in FIG. 9B, a first subpixel (SP1) according to an embodiment of the present disclosure can include a reflective electrode (201), a transparent electrode (203), an light emitting layer (220), and a second electrode (230).

The light emitting layer (220) according to another embodiment of the present disclosure can include a first stack (221), a first charge generation layer (1st CGL) (222), a second stack (223), a second charge generation layer (2nd CGL) (224), and a third stack (225). In this case, the first stack (221) can emit, for example, blue (B) light; the second stack (223) can emit, for example, green (G), red (R), and yellow-green (YG) light; and the third stack (225) can emit blue (B) light, for example.

The second charge generation layer (2nd CGL) (224) can be disposed on the second stack (223). Specifically, the second charge generation layer (224) can be disposed between the second stack (223) and the third stack (225). By being disposed between the second stack (223) and the third stack (225), the second charge generation layer (224) can adjust the charge balance between the second and third stacks.

The third stack (225) can include a third hole transport layer (3rd HTL) (225a), a fifth emission layer (5th EML) (225b), and a third electron transport layer (3rd ETL) (225c).

The third hole transport layer (3rd HTL) (225a) can be disposed on the second charge generation layer (2nd CGL) (224). The third hole transport layer (3rd HTL) (225a) can transport holes, which have moved from the second charge generation layer (2nd CGL) (224), to the fifth emission layer (5th EML) (225b). Meanwhile, a hole injection layer (HIL) can additionally be disposed between the second charge generation layer (2nd CGL) (224) and the third hole transport layer (3rd HTL) (225a).

The fifth emission layer (5th EML) (225b) is a layer that emits blue (B) light, and can emit blue light through the recombination of holes and electrons respectively supplied from the third hole transport layer (3rd HTL) (225a) and the third electron transport layer (3rd ETL) (225c).

The third electron transport layer (3rd ETL) (225c) can be disposed on the fifth emission layer (5th EML) (225b). The third electron transport layer (3rd ETL) (225c) can transport electrons, which have moved from the second electrode (230), to the fifth emission layer (5th EML) (225b). Meanwhile, an electron injection layer (EIL) can additionally be disposed between the second electrode (230) and the third electron transport layer (3rd ETL) (225c).

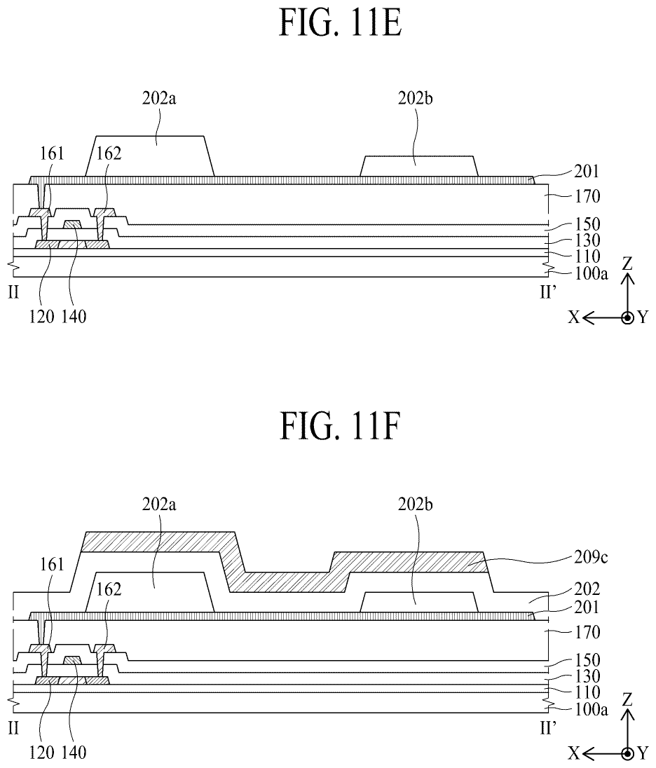

FIG. 10A is a graph of intensity according to wavelength at the front of a subpixel according to an embodiment of the present disclosure and a subpixel according to a comparative example, and FIG. 10B is a graph of intensity according to wavelength at the side of a subpixel according to an embodiment of the present disclosure and a subpixel according to a comparative example.

In each of FIGS. 10A and 10B, the solid line (Example) relates to the organic light emitting display device according to the embodiment of FIG. 7, the dotted line relates to the organic light emitting display device according to Comparative Example 1, and the one dot chain line relates to the organic light emitting display device according to Comparative Example 2. In this case, Comparative Examples 1 and 2 relate to cases in which transparent electrodes are provided without forming a separate step, and specifically, Comparative Example 1 relates to the case in which the distance between the first electrode and the second electrode is adjusted without considering whether a micro cavity is formed, and Comparative Example 2 relates to the case in which the distance between the first electrode and the second electrode is adjusted considering whether a micro cavity is formed. Therefore, in the front view (see FIG. 10A), the light emission intensity and efficiency of Comparative Example 2 can be higher than those of Comparative Example 1. On the other hand, in the case of Comparative Example 2 from the side (see FIG. 10B), the light emission intensity and efficiency can be lower than in the case of Comparative Example 1, or the wavelength of the emitted color can be far from the wavelength range of the color to be displayed, resulting in lower color purity.

First, as can be seen in FIG. 10A, it was confirmed that the organic light emitting display device according to one embodiment of the present disclosure emits light with a higher intensity in the vicinity of 450 nm and the vicinity of 550 nm, compared to Comparative Example 1. For example, according to one embodiment of the present disclosure, since the height of the transparent electrode (203) is adjusted so that the height between the reflective electrode (201) and the second electrode (230) becomes a multiple of a half wavelength of one of red (R), green (G), and blue (B), it can be confirmed that a relatively high light emission intensity can be obtained.

Next, as can be seen in FIG. 10B, it can be confirmed that the organic light emitting display device according to one embodiment of the present disclosure has wavelengths having maximum intensity in the vicinity of 450 nm and the vicinity of 550 nm formed at positions relatively closer to Comparative Example 1 than to Comparative Example 2. For example, it can be confirmed that the color purity can be improved by forming the wavelength of the color emitted from the side by the transparent electrode (203) provided in such a step manner so as to be close to the range of the wavelength of the color to be displayed.

As a result, when looking at FIGS. 10A and 10B together, according to one embodiment of the present disclosure, the problem of color purity decreasing according to the viewing angle from the side can be improved while improving the light emission efficiency from the front by the micro cavity effect.

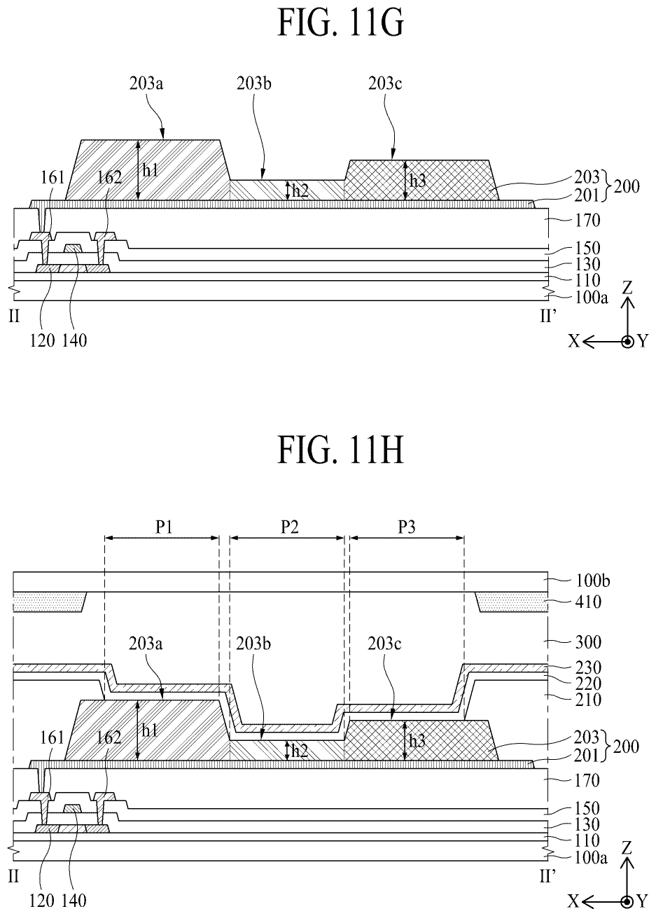

FIGS. 11A to 11H are process cross-sectional views of a subpixel according to one embodiment of the present disclosure. In this case, FIGS. 11A to 11H correspond to a cross-section along line II-II′ of FIG. 6. Meanwhile, the embodiment of FIGS. 11A to 11H relates to the embodiment of FIG. 7, and the same reference numerals are given to the same components, and repeated descriptions are omitted.

First, as can be seen in FIG. 11A, a first substrate (100a), a buffer layer (110), an active layer (120), a gate insulating film (130), a gate electrode (140), an interlayer insulating film (150), a source electrode (161), a drain electrode (162), a planarization layer (170), and a reflective electrode (201) can be formed in sequence. In this case, the reflective electrode (201) can be pattern-formed to correspond to an area where a pixel is disposed.

Next, as can be seen in FIG. 11B, a transparent electrode layer (202) can be disposed on the reflective electrode (201). After forming the transparent electrode layer (202), a first resist (209a) is formed on the transparent electrode layer (202) so as to correspond to the first region (P1 in FIG. 7) in order to form a first portion (203a in FIG. 7) of the transparent electrode (203).

Next, as can be seen in FIG. 11C, the transparent electrode layer (202) can be etched using the first resist (209a) as a mask. In this case, after the transparent electrode layer (202) is etched, a first pattern (202a) can be formed in an area corresponding to the first area (see P1 of FIG. 7).

As can be seen in FIG. 11D, a transparent electrode layer (202) can be disposed on the reflective electrode (201) and the first pattern (202a). After the transparent electrode layer (202) is formed, a second resist (209b) is disposed on the transparent electrode layer (202) to correspond to the first region (see P1 in FIG. 7) and the third region (see P3 in FIG. 7) in order to form a first portion (see 203a in FIG. 7) and a third portion (see 203c in FIG. 7) of the transparent electrode (203).

Next, as can be seen in FIG. 11E, the transparent electrode layer (202) can be etched using the second resist (209b) as a mask. In this case, after the transparent electrode layer (202) is etched, a first pattern (202a) and a second pattern (202b) can be formed in regions corresponding to the first region (see P1 of FIG. 7) and the third region (see P3 of FIG. 7), respectively. In this case, the length of the first pattern (202a) in the third direction (Z) is formed to be longer than the length of the second pattern (202b) in the third direction (Z).

Next, as can be seen in FIG. 11F, a transparent electrode layer (202) can be disposed on the reflective electrode (201), the first pattern (202a), and the second pattern (202b). After the transparent electrode layer (202) is formed, a third resist (209c) is formed on the transparent electrode layer (202) to correspond to the first region (see P1 in FIG. 7) to the third region (see P1 to P3 in FIG. 7) in order to form the first to third portions (see 203a to 203c in FIG. 7) of the transparent electrode (203).

Next, as can be seen in FIG. 11G, the transparent electrode layer (202) can be etched using the third resist (209c) as a mask. In this case, after the transparent electrode layer (202) is etched, the first portion (203a), the second portion (203b), and the third portion (203c) can be formed in regions corresponding to the first region (see P1 of FIG. 7), the second region (see P2 of FIG. 7), and the third region (see P3 of FIG. 7), respectively. In this case, the first portion (203a), the second portion (203b), and the third portion (203c) can have a first height (h1), a second height (h2), and a third height (h3), respectively.

Finally, as shown in FIG. 11H, by forming the bank (210) to cover a portion of the first electrode (200), and sequentially forming the light emitting layer (220), the second electrode (230), the encapsulation layer (300), the black matrix (410) and the second substrate (100b) thereon, an organic light emitting display device according to an embodiment of the present disclosure can be implemented.

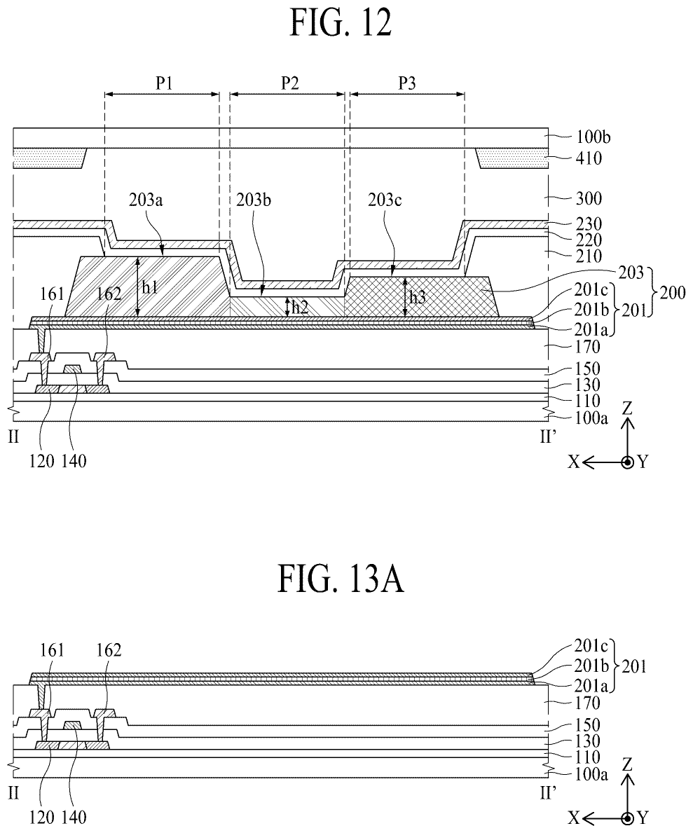

FIG. 12 is a cross-sectional view of a subpixel according to another embodiment of the present disclosure. In this case, FIG. 12 corresponds to a cross-section along line II-II′ of FIG. 6. Meanwhile, the embodiment of FIG. 12 is identical to the embodiment of FIG. 7 except for the configuration of the reflective electrode, so the following description will focus on the different configuration.

Referring to FIG. 12, the subpixel according to another embodiment of the present disclosure comprises a first substrate (100a), a buffer layer (110), an active layer (120), a gate insulating film (130), a gate electrode (140), an interlayer insulating film (150), a source electrode (161), a drain electrode (162), a planarization layer (170), a first electrode (200), a bank (210), a light emitting layer (220), a second electrode (230), an encapsulation layer (300), a black matrix (410), and a second substrate (100b).

The first electrode (200) is composed of a reflective electrode (201) and a transparent electrode (203).

Unlike the embodiment of FIG. 7, according to another embodiment of the present disclosure, the reflective electrode (201) includes a first layer (201a), a second layer (201b), and a third layer (201c) sequentially provided on the flattening layer (170).

According to an embodiment of the present disclosure, the first layer (201a) and the third layer (201c) can be formed of the same material, and the second layer (201b) can be formed of a material having a relatively higher reflectivity than the first layer (201a) and the third layer (201c). For example, the first layer (201a) and the third layer (201c) can include indium tin oxide (ITO), and the second layer (201b) can include aluminum (Al), but is not limited thereto.

According to an embodiment of the present disclosure, the first layer (201a) and the third layer (201c) are formed by including the same material, but the first layer (201a) and the third layer (201c) can be formed by including different crystal structures. For example, the first layer (201a) can be formed by including an amorphous material, and the third layer (201c) can be formed by including a crystalline material. By forming in this manner, the third layer (201c) may not be damaged during the process of etching and forming the first portion (203a) to the third portion (203c) of the transparent electrode (203), and the distance between the upper surface of the reflective electrode (201) and the second electrode (230) can be uniformly maintained as a distance for forming a micro cavity.

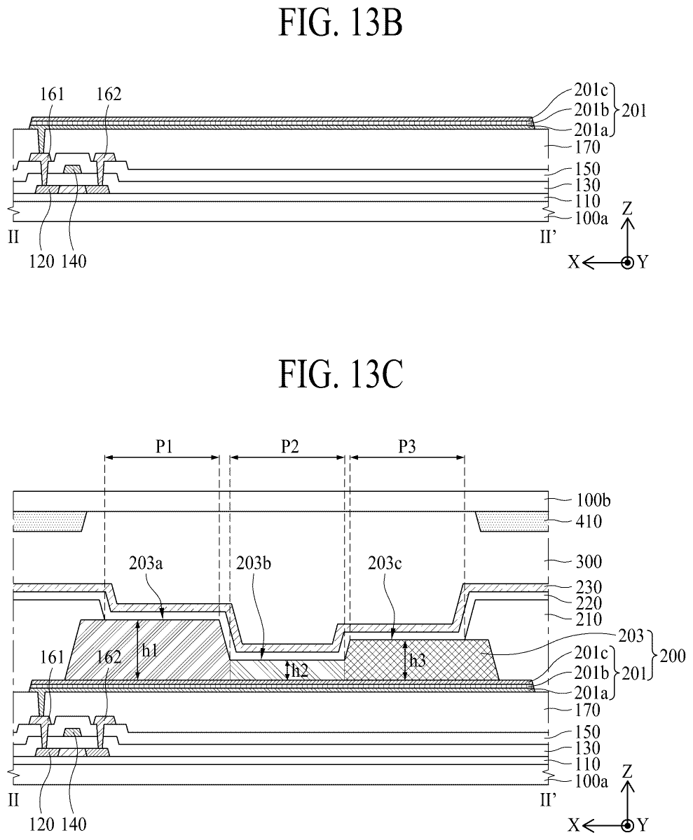

FIGS. 13A to 13C are process cross-sectional views of a subpixel according to one embodiment of the present disclosure. In this case, FIGS. 13A to 13C correspond to a cross-section along line II-II′ of FIG. 6. Meanwhile, the embodiment of FIGS. 13A to 13C relates to the embodiment of FIG. 12, and the same reference numerals are given to the same components, and repeated descriptions are omitted.

First, as can be seen in FIG. 13A, a first substrate (100a), a buffer layer (110), an active layer (120), a gate insulating film (130), a gate electrode (140), an interlayer insulating film (150), a source electrode (161), a drain electrode (162), a planarization layer (170), and a reflective electrode (201) can be formed in sequence. In this case, the reflective electrode (201) can be pattern-formed to correspond to an area where a pixel is formed.

Furthermore, the reflective electrode (201) can be formed to be sequentially provided as a first layer (201a), a second layer (201b), and a third layer (201c) on the flattening layer (170).

The first layer (201a) and the third layer (201c) can be formed of, for example, indium tin oxide (ITO), and the second layer (202b) can be formed of, for example, aluminum (Al).

Meanwhile, the first layer (201a) and the third layer (201c) are formed on the planarization layer (170) so as to have the same material and the same crystal structure. The first layer (201a) and the third layer (201c) can be formed by including an amorphous material. For example, the first layer (201a) and the third layer (201c) are formed by including amorphous indium-tin oxide (ITO).

Next, as can be seen in FIG. 13B, by performing a heat treatment process on the third layer (201c), the third layer (201c) can include a crystalline material. For example, the first layer (201a) can include amorphous indium-tin oxide (ITO), while the third layer (201c) can include crystalline indium-tin oxide (ITO).

According to an embodiment of the present disclosure, since the third layer (201c) is formed by including a crystalline material, during the process of forming the transparent electrode (203) on the reflective electrode (201), the third layer (201c) can maintain a constant thickness without being damaged during the process of forming the first part to the third part (see 203a to 203c of FIG. 12) of the transparent electrode (203).

Finally, as shown in FIG. 13C, the transparent electrode (203) is disposed on the reflective electrode (201) to form the first electrode (200), the bank (210) is formed to cover a portion of the first electrode (200), and the light emitting layer (220), the second electrode (230), the encapsulation layer (300), the black matrix (410) and the second substrate (100b) are formed thereon in order, thereby implementing an organic light emitting display device according to an embodiment of the present disclosure.

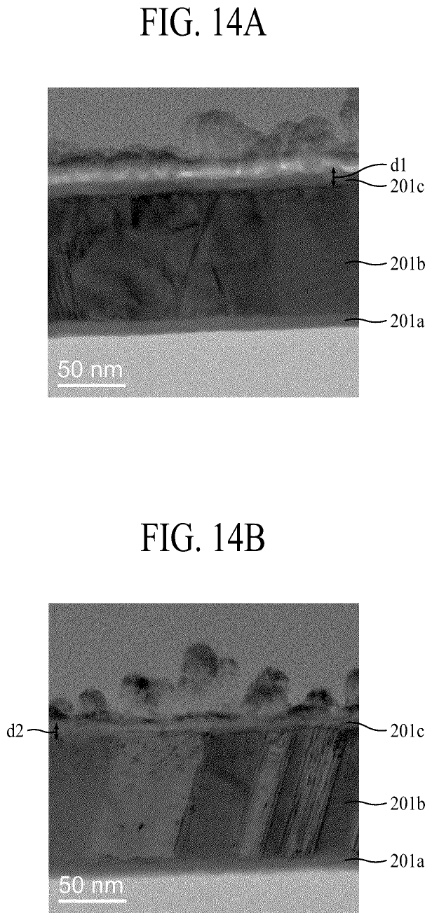

FIG. 14A and FIG. 14B are TEM images of a first electrode provided in a subpixel according to another embodiment of the present disclosure. In this case, FIG. 14A relates to a case where the first layer (201a), the second layer (201b), and the third layer (201c) were formed and then exposed to an etchant for 75 seconds, and FIG. 14B relates to a case where the first layer (201a), the second layer (201b), and the third layer (201c) were formed and then exposed to an etchant for 150 seconds.

First, as shown in FIG. 14A, when exposed to the etchant for 75 seconds, the third layer (201c) was formed to the first thickness (d1). In this case, it was found that the first thickness (d1) was measured to be 86 Å.

Next, as can be seen in FIG. 14B, when exposed to the etchant for 150 seconds, the third layer (201c) was formed to the second thickness (d2). In this case, it was found that the second thickness (d2) was measured to be 91 Å.

Looking at FIG. 14A and FIG. 14B comprehensively, it can be confirmed that the thickness change of the third layer (201c) according to the degree of exposure to the etchant is 86 Å and 91 Å, respectively, which is only at a level of no difference when considering the experimental measurement deviation. Accordingly, it can be confirmed that the degree of thickness change of the reflective electrode (201) according to the exposure to the etchant is at a very small level because the third layer (201c) is formed by including a crystalline material.

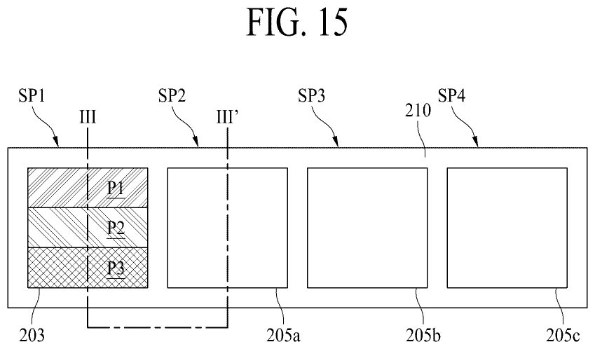

FIG. 15 is a plan view of a subpixel according to another embodiment of the present disclosure. In this case, the embodiment of FIG. 15 relates to the first subpixel (SP1) to the fourth subpixel (SP4), and since the first subpixel (SP1) according to the embodiment of FIG. 15 is the same as the subpixel according to the embodiment of FIG. 6, the following description will focus on different configurations.

As can be seen in FIG. 15, a subpixel according to another embodiment of the present disclosure includes a first subpixel SP1, a second subpixel SP2, a third subpixel SP3, and a fourth subpixel SP4. In this case, for example, the first subpixel SP1 can display white (W), the second subpixel SP2 can display red (R), the third subpixel SP3 can display blue (B), and the fourth subpixel SP4 can display blue (B).

According to an embodiment of the present disclosure, the first subpixel (SP1) displaying the white color (W) includes a transparent electrode (203) having different heights in the third direction (Z), so as to include a first region (P1), a second region (P2), and a third region (P3) according to the different heights of the transparent electrode (203). On the other hand, the second subpixel (SP2) to the fourth subpixel (SP4) include transparent electrodes (205a, 205b, 205c) having the same height in the third direction (Z).

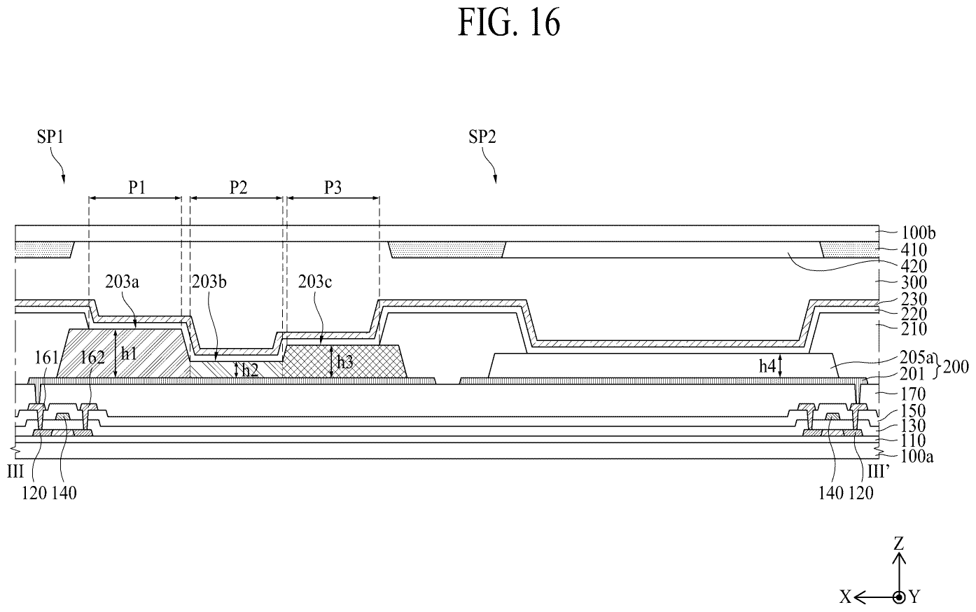

FIG. 16 is a cross-sectional view of a subpixel according to another embodiment of the present disclosure. In this case, FIG. 16 corresponds to a cross-section along line III-III′ of FIG. 15. Meanwhile, the embodiment of FIG. 16 illustrates the first subpixel (SP1) and the second subpixel (SP2) of the embodiment of FIG. 15. Since the first subpixel (SP1) according to the embodiment of FIG. 16 is the same as the first subpixel (SP1) according to the embodiment of FIG. 7, the following description will focus on the different configurations

As can be seen in FIG. 16, a first subpixel (SP1) and a second subpixel (SP2) according to another embodiment of the present disclosure include a first substrate (100a), a buffer layer (110), an active layer (120), a gate insulating film (130), a gate electrode (140), an interlayer insulating film (150), a source electrode (161), a drain electrode (162), a planarization layer (170), a first electrode (200), a bank (210), a light emitting layer (220), a second electrode (230), an encapsulation layer (300), a black matrix (410), a color filter (420), and a second substrate (100b).

The first electrode (200) provided in the first subpixel (SP1) includes transparent electrodes (203) having different heights (h1 to h3). In addition, since the first subpixel (SP1) emits white (W), a separate color filter (420) may not be disposed between the black matrices (410).

Meanwhile, unlike the first subpixel (SP1), the first electrode (200) provided in the second subpixel (SP2) according to another embodiment of the present disclosure includes a reflective electrode (201) and a first transparent electrode (205a). In this case, the first transparent electrode (205a) is not formed in a step structure, and can be formed with the same fourth height (h4) along the second direction (X).

The second subpixel (SP2) is disposed on the encapsulation layer (300) and can additionally include a color filter (420) disposed between the black matrices (410). The color filter (420) can transmit light of any one color among red (R), green (G), and blue (B), and the color of light displayed by the second subpixel (SP2) can be determined according to the color of light transmitted by the color filter (420).

For example, the color filter (420) provided in the second subpixel (SP2) can transmit red (R) light, and in this case, the second subpixel (SP2) can display red (R). Meanwhile, the third subpixel (see SP3 of FIG. 15) and the fourth subpixel (see SP4 of FIG. 15) can be provided with a color filter that transmits blue (B) and a color filter that transmits green (G), respectively, and in this case, the third subpixel (see SP3 of FIG. 15) can display blue (B) and the fourth subpixel (see SP4 of FIG. 15) can display green (G).

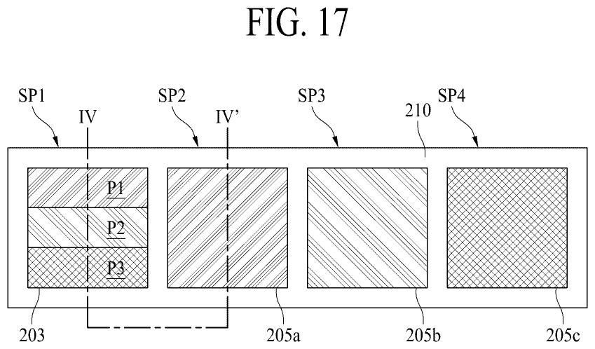

FIG. 17 is a plan view of a subpixel according to another embodiment of the present disclosure. In this case, the embodiment of FIG. 17 relates to the first to fourth subpixels (SP1 to SP4), and is the same as the embodiment of FIG. 15 except for the second to fourth subpixels (SP2 to SP4). Accordingly, the following description will focus on the different configurations.

As can be seen in FIG. 17, a subpixel according to another embodiment of the present disclosure includes a first subpixel (SP1), a second subpixel (SP2), a third subpixel (SP3), and a fourth subpixel (SP4). In this case, for example, the first subpixel (SP1) can display white (W), the second subpixel (SP2) can display red (R), the third subpixel (SP3) can display blue (B), and the fourth subpixel (SP4) can display green (G).

The first subpixel (SP1) displaying the white (W) is formed by including transparent electrodes (203) having different heights in the third direction (Z), so as to include a first region (P1), a second region (P2), and a third region (P3) according to the different heights of the transparent electrodes (203).

According to an embodiment of the present disclosure, the second subpixel (SP2) displaying the red color (R) can include a first transparent electrode (205a) having a first height (see h1 of FIG. 7) of the transparent electrode (203) provided in the first region (P1) of the first subpixel (SP1), and the third subpixel (SP3) displaying the blue color (B) can include a second transparent electrode (205b) having a second height (see h2 of FIG. 7) of the transparent electrode (203) provided in the second region (P2) of the first subpixel (SP1).

The fourth subpixel (SP4) displaying the green color (G) can include a third transparent electrode (205c) having a third height (see h3 of FIG. 7) of the transparent electrode (203) provided in the third region (P3) of the first subpixel (SP1).

By being formed in this manner, not only is the light emission efficiency at the front of the first subpixel (SP1) emitting white (W) light increased, and the color purity at the side increased, but also high light emission efficiency can be achieved in the second subpixel (SP2) and the fourth subpixel (SP4).

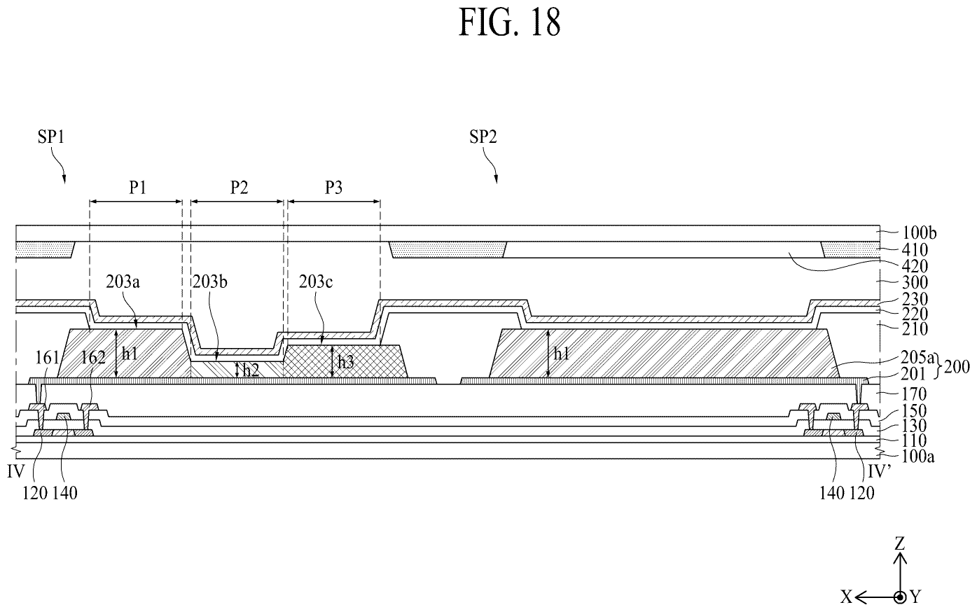

FIG. 18 is a cross-sectional view of a subpixel according to another embodiment of the present disclosure. In this case, FIG. 18 corresponds to a cross-section along line IV-IV′ of FIG. 17. Meanwhile, the embodiment of FIG. 18 illustrates the first subpixel (SP1) and the second subpixel (SP2) of the embodiment of FIG. 17. Since the embodiment of FIG. 18 is the same as the embodiment of FIG. 16 except for the first transparent electrode (205a) provided in the second subpixel (SP2), the following description will focus on the different configuration.

According to another embodiment of the present disclosure, the first transparent electrode (205a) provided in the second subpixel (SP2) can have a first height (h1) in the third direction (Z).

In this case, the first height (h1) can be adjusted such that the distance between the reflective electrode (201) and the second electrode (230) in the second subpixel (SP2) becomes an integer multiple of the half-wavelength of red (R) light emitted from the light emitting layer (220). Accordingly, red (R) light among the light emitted from the light emitting layer (220) of the second subpixel (SP2) undergoes repeated reflection between the reflective electrode (201) and the second electrode (230), thereby forming a micro cavity. Accordingly, the second subpixel (SP2) can display red (R) light with relatively high efficiency.

Meanwhile, the third subpixel (see SP3 of FIG. 17) displaying the blue (B) and the fourth subpixel (see SP4 of FIG. 17) displaying the green (G) each include a second transparent electrode (205b) having a second height (h2) and a third transparent electrode (205c) having a third height (h3). By being configured in this way, the blue (B) and green (G) light emitted from the light emitting layer (220) of the third and fourth subpixels (see SP3 and SP4 in FIG. 17) undergo repeated reflection between the reflective electrode (201) and the second electrode (230), thereby forming a micro cavity. Accordingly, the third subpixel and the fourth subpixel (see SP3 and SP4 of FIG. 17) can display blue (B) and green (G) light with relatively high efficiency, respectively.

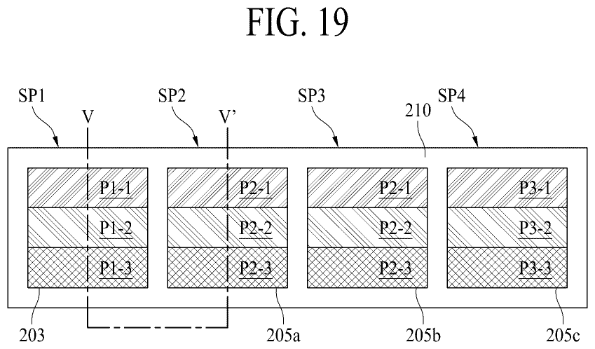

FIG. 19 is a plan view of a subpixel according to another embodiment of the present disclosure. In this case, the embodiment of FIG. 19 relates to the first subpixel (SP1) to the fourth subpixel (SP4), and is identical to the embodiment of FIG. 15 except for the second subpixel (SP2) to the fourth subpixel (SP4), so the following description will focus on the different configurations.

As can be seen in FIG. 19, a subpixel according to another embodiment of the present disclosure includes a first subpixel (SP1), a second subpixel (SP2), a third subpixel (SP3), and a fourth subpixel (SP4). In this case, for example, the first subpixel (SP1) can display white (W), the second subpixel (SP2) can display red (R), the third subpixel (SP3) can display blue (B), and the fourth subpixel (SP4) can display green (G).

According to another embodiment of the present disclosure, the first subpixel (SP1) to the fourth subpixel (SP4) are all formed by including transparent electrodes (203) having different heights in the third direction (Z), so that according to the different heights of the transparent electrodes (203, 205a, 205b, 205c), a first region (P1-1, P2-1, P3-1, P4-1), a second region (P1-2, P2-2, P3-2, P4-2) and a third region (P1-3, P2-3, P3-3, P4-3) are formed.

Meanwhile, in FIG. 19, the first subpixel (SP1) to the fourth subpixel (SP4) are each provided with only the first region to the third region of three rows and one column, but this is not limited thereto, and the configuration and arrangement of the first region to the third region of each subpixel (SP1 to SP4) can be freely changed depending on the light emitting efficiency of the first subpixel (SP1) to the fourth subpixel (SP4).

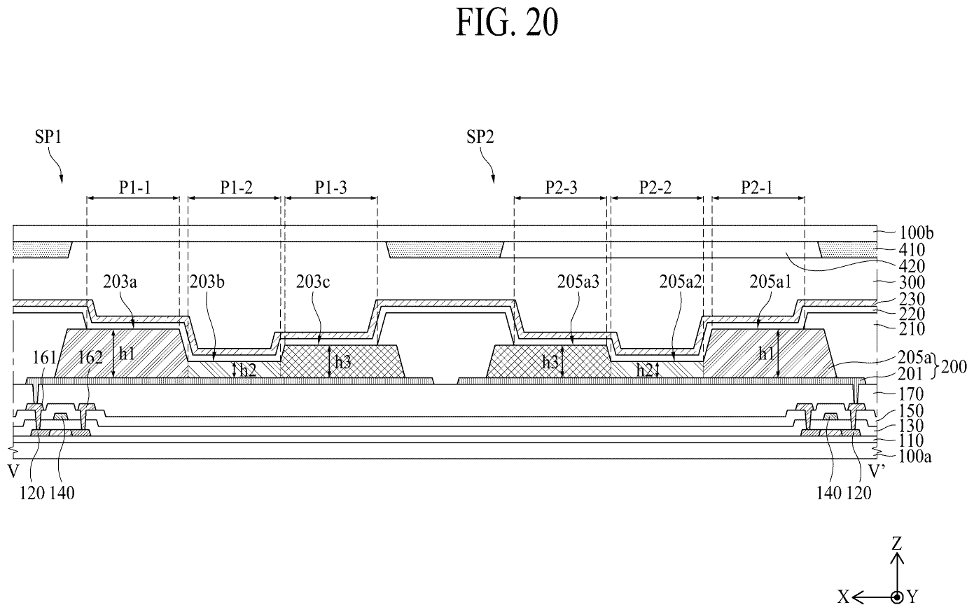

FIG. 20 is a cross-sectional view of a subpixel according to another embodiment of the present disclosure. In this case, FIG. 20 corresponds to a cross-section along line V-V′ of FIG. 19. Meanwhile, the embodiment of FIG. 20 illustrates the first subpixel (SP1) and the second subpixel (SP2) of the embodiment of FIG. 19. Since the embodiment of FIG. 20 is the same as the embodiment of FIG. 16 except for the first transparent electrode (205a) provided in the second subpixel (SP2), the following description will focus on the different configuration.

The first transparent electrode (205a) can be disposed on the reflective electrode (201).

The first transparent electrode (205a) can include a first portion (205a1) having a first height (h1), a second portion (205a2) having a second height (h2), and a third portion (205a3) having a third height (h3) within the light emitting area of the second subpixel (SP2). The first height (h1) can be, for example, greater than the second height (h2) and the third height (h3), and the third height (h3) can be greater than the second height (h2). In this case, the first height (h1) to the third height (h3) can be defined as the shortest distances from the reflective electrode (201) to the upper surfaces of the first portion (205a1) to the third portion (205a3), respectively.

According to another embodiment of the present disclosure, by controlling the step structure of the first transparent electrode (205a), the resonance distance between the reflective electrode (201) and the second electrode (230) can be controlled. Specifically, by controlling the height of the first portion (205a1) to the third portion (203c) of the first transparent electrode (205a), the resonance distance between the reflective electrode (201) and the second electrode (230) can be controlled. By controlling the resonance distance, a micro cavity can be formed in the red (R) light, green (G) light, and blue (B) light emitted from the light emitting layer (220).

In the first region (P1) overlapping with the first portion (205a1), the first height (h1) can be adjusted so that a micro cavity is formed for one of red (R), green (G), or blue (B) light. In the second region (P2) overlapping with the second portion (205a2), the second height (h2) can be adjusted so that a micro cavity is formed for another of the red, green, or blue light. In the third region (P3) overlapping with the third portion (205a3), the third height (h3) can be adjusted so that a micro cavity is formed for the remaining one of the red, green, or blue light. Accordingly, the first height (h1) can be set such that the distance between the reflective electrode (201) and the second electrode (230) is a multiple of a half wavelength of any one of red (R) light, green (G) light, and blue (B) light. The second height (h2) can be set such that the distance between the reflective electrode (201) and the second electrode (230) is a multiple of a half wavelength of any one of the other of red (R) light, green (G) light, and blue (B) light. The third height (h3) can be set such that the distance between the reflective electrode (201) and the second electrode (230) is a multiple of a half wavelength of any one of the other of red (R) light, green (G) light, and blue (B) light.

According to one embodiment of the present disclosure, since the heights of the first portion (205a1) to the third portion (203c) are formed differently, the first region (P1) to the third region (P3) within the second subpixel (SP2) can have different optical characteristics.

For example, by adjusting the first height (h1) in the first region (P1) overlapping the first portion (205a1), the distance between the reflective electrode (201) and the second electrode (230) can be set to be a multiple of a half wavelength of red (R) light, the second height (h2) in the second region (P2) overlapping the second portion (205a2) can be adjusted to be a multiple of a half wavelength of blue (B) light, and the third height (h3) in the third region (P3) overlapping the third portion (205a3) can be adjusted to be a multiple of a half wavelength of green (G) light between the reflective electrode (201) and the second electrode (230).

In this case, in the second subpixel (SP2), a micro cavity can be formed for red (R) light in the first region (P1), for blue (B) light in the second region (P2), and for green (G) light in the third region (P3). Accordingly, the light emitted from the second subpixel (SP2) can have high emission efficiency.

Meanwhile, the same content described for the second subpixel (SP2) can be equally applied to the third subpixel (SP3) emitting blue (B) and the fourth subpixel (SP4) emitting green (G)

Although the embodiments of the present disclosure have been described in more detail with reference to the attached drawings, the present disclosure is not necessarily limited to these embodiments, and various modifications can be made without departing from the technical idea of the present disclosure. Accordingly, the embodiments disclosed in the present disclosure are not intended to limit the technical idea of the present disclosure, but to explain it, and the scope of the technical idea of the present disclosure is not limited by these embodiments. Therefore, it should be understood that the embodiments described above are examples in all aspects and not restrictive. The protection scope of the present disclosure should be interpreted by the claims, and all technical ideas within a scope equivalent thereto should be interpreted as being included in the scope of the rights of the present disclosure.

According to the present disclosure as described above, the following effects are achieved.

According to one or more embodiments of the present disclosure, the light emission efficiency at the front of a sub pixel emitting white light can be improved by a transparent electrode formed with a step, while preventing or reducing degradation in color purity when viewed from an oblique angle.

According to one or more embodiments of the present disclosure, by including a layer including a crystalline material on the upper surface of a reflective electrode, even if repetitive etching is performed to form a step structure of a transparent electrode, the resonance distance for forming a micro cavity can be controlled so as not to be broken.

The effects of the present disclosure are not limited to the effects mentioned above, and other effects not mentioned will be clearly understood by those skilled in the art from the description below.

What is claimed is:

1. An organic light emitting display device comprising:
a substrate;
a subpixel disposed on the substrate;
a first electrode provided in the subpixel, the first electrode including a reflective electrode and a transparent electrode disposed on the reflective electrode;
a light emitting layer disposed on the first electrode; and
a second electrode disposed on the light emitting layer,
wherein the transparent electrode includes a first portion and a second portion, the first portion having a first height, and the second portion having a second height different from the first height.

2. The organic light emitting display device of claim 1, wherein the light emitting layer comprises:
a first emission layer configured to emit a light of a first color; and
a second emission layer disposed on the first emission layer, the second emission layer configured to emit a light of a second color different from the first color,
wherein the first height is set to satisfy a condition where a distance from a portion of the reflective electrode overlapping the first portion to the second electrode is a multiple of a half wavelength of light of any one of red light, green light, and blue light, and
wherein the second height is set to satisfy a condition where a distance from a portion of the reflective electrode overlapping the second portion to the second electrode is a multiple of a half wavelength of light of any one of red light, green light, and blue light.

3. The organic light emitting display device of claim 1, wherein an upper surface of the first portion and an upper surface of the second portion comprise different areas.

4. The organic light emitting display device of claim 1, wherein the transparent electrode further comprises a third portion having a third height different from the first height or the second height.

5. The organic light emitting display device of claim 4, wherein the light emitting layer comprises:
a first emission layer configured to emit a light of a first color;
a second emission layer disposed on the first emission layer, the second emission layer configured to emit a light of a second color different from the first color; and
a third emission layer disposed on the second emission layer, the third emission layer configured to emit a light of a third color different from the first and second colors,
wherein the first height is set to satisfy a condition where a distance from a portion of the reflective electrode overlapping the first portion to the second electrode is a multiple of a half wavelength of light of any one of red light, green light, and blue light,
wherein the second height is set to satisfy a condition where a distance from a portion of the reflective electrode overlapping the second portion to the second electrode is a multiple of a half wavelength of light of any one of red light, green light, and blue light, and
wherein the third height is set to satisfy a condition where a distance from a portion of the reflective electrode overlapping the third portion to the second electrode is a multiple of a half wavelength of light of any one of red light, green light, and blue light.

6. The organic light emitting display device of claim 1, wherein the transparent electrode comprises:
a plurality of first portions having the first height; and
a plurality of second portions having the second height different from the first height,
wherein the plurality of first portions and the plurality of second portions form a mesh structure.

7. The organic light emitting display device of claim 6, wherein the light emitting layer comprises:
a first emission layer configured to emit a light of a first color; and
a second emission layer disposed on the first emission layer, the second emission layer configured to emit a light of a second color different from the first color,
wherein the first height is set to satisfy a condition where a distance from a portion of the reflective electrode overlapping the first portion to the second electrode is a multiple of a half wavelength of light of any one of red light, green light, and blue light, and
wherein the second height is set to satisfy a condition where a distance from a portion of the reflective electrode overlapping the second portion to the second electrode is a multiple of a half wavelength of light of any one of red light, green light, and blue light.

8. The organic light emitting display device of claim 1, wherein the light emitting layer comprises:
a first emission layer configured to emit a blue light;
a first charge generation layer disposed on the first emission layer;
a second emission layer disposed on the first charge generation layer, the second emission layer configured to emit at least one of a red light, a yellow-green light, and a green light;
a second charge generation layer disposed on the second emission layer; and
a third emission layer disposed on the second charge generation layer, the third emission layer configured to emit the blue light.

9. The organic light emitting display device of claim 1, wherein the first electrode comprises:
a first layer;
a second layer disposed on the first layer, the second layer including a material having a higher reflectivity than the first layer; and
a third layer disposed on the second layer, the third layer including a material same as the first layer,
wherein the first layer includes an amorphous material and the third layer includes a crystalline material.

10. An organic light emitting display device comprising:
a substrate;
a plurality of subpixels including a first subpixel and a second subpixel disposed on the substrate;
a first electrode provided in each of the plurality of subpixels, the first electrode including a reflective electrode and a transparent electrode on the reflective electrode;
a light emitting layer disposed on the first electrode; and
a second electrode disposed on the light emitting layer,
wherein the transparent electrode of the first subpixel includes a first portion having a first height and a second portion having a second height; and
wherein the transparent electrode of the second subpixel has the first height.

11. The organic light emitting display device of claim 10, wherein the light emitting layer comprises:
a first emission layer configured to emit a light of a first color; and
a second emission layer disposed on the first emission layer, the second emission layer configured to emit a light of a second color different from the first color,
wherein the first height is set to satisfy a condition where a distance from a portion of the reflective electrode overlapping the first portion to the second electrode is a multiple of a half wavelength of light of any one of red light, green light, and blue light, and
wherein the second height is set to satisfy a condition where a distance from a portion of the reflective electrode overlapping the second portion to the second electrode is a multiple of a half wavelength of light of any one of red light, green light, and blue light.

12. The organic light emitting display device of claim 10, wherein the first subpixel is configured to display white color, and
wherein the second subpixel is configured to display one of red, green, and blue color.

13. The organic light emitting display device of claim 10, wherein the plurality of subpixels further comprises a third subpixel disposed on the substrate, and
wherein a transparent electrode of the third subpixel has the second height.

14. The organic light emitting display device of claim 10, further comprising:
a color filter provided to overlap the second subpixel,
wherein the color filter transmits at least one of red light, green light, and blue light.

15. The organic light emitting display device of claim 14, wherein the light emitting layer comprises:
a first emission layer configured to emit a light of a first color; and
a second emission layer disposed on the first emission layer, the second emission layer configured to emit a light of a second color different from the first color,
wherein the first height is set to satisfy a condition where a distance from a portion of the reflective electrode overlapping the first portion to the second electrode is a multiple of a half wavelength of light of any one of red light, green light, and blue light, and
wherein the second height is set to satisfy a condition where a distance from a portion of the reflective electrode overlapping the second portion to the second electrode is a multiple of a half wavelength of light of any one of red light, green light, and blue light.

16. The organic light emitting display device of claim 14, wherein the plurality of subpixels further comprises a third subpixel,
wherein the first subpixel is configured to display white color,
wherein the second subpixel is configured to display one of red, green, and blue color, and
wherein the third subpixel is configured to display another one of red, green, and blue color.

17. An organic light emitting display device comprising:
a substrate;
a plurality of subpixels disposed on the substrate;
a first electrode disposed in each of the plurality of subpixels;
a light emitting layer disposed on the first electrode; and
a second electrode disposed on the light emitting layer,
wherein at least one of the plurality of subpixels implements a microcavity effect for at least two of red light, green light, and blue light.

18. The organic light emitting display device of claim 17, wherein the light emitting layer comprises:
a first emission layer configured to emit a light of a first color; and
a second emission layer disposed on the first emission layer, the second emission layer configured to emit a light of a second color different from the first color.

19. The organic light emitting display device of claim 17, wherein the plurality of subpixels includes a white subpixel, and
wherein the white subpixel implements the microcavity effect for at least two of red light, green light, and blue light.

20. The organic light emitting display device of claim 19, wherein the plurality of subpixels further includes red subpixels, green subpixels, and blue subpixels, and
wherein a light emitting area of one of the red subpixels, the green subpixels, and the blue subpixels implements the microcavity effect for one of red light, green light, and blue light.
